(19) United States
(12) Patent Application Publication
(10) Pub. No.: US 2026/0013197 A1
(43) Pub. Date: Jan. 8, 2026

(54) INTEGRATED CIRCUIT DEVICE

(71) Applicant: Samsung Electronics Co., Ltd., Suwon-si (KR)

(72) Inventors: Bokyoung Lee, Suwon-si (KR); Sujin Gwon, Suwon-si (KR); Hyunwoo Kim, Suwon-si (KR); Hyunchul Song, Suwon-si (KR); Taeyeon Shin, Suwon-si (KR); Suekwoo Choi, Suwon-si (KR)

(21) Appl. No.: 19/005,101

(22) Filed: Dec. 30, 2024

(30) Foreign Application Priority Data
Jul. 5, 2024 (KR) 10-2024-0089118

(51) Int. Cl. H10D 64/23; H10D 30/00; H10D 30/43; H10D 62/10; H10D 84/83

(52) U.S. Cl. CPC H10D 64/251; H10D 30/43; H10D 30/502; H10D 62/121; H10D 84/832

(57) ABSTRACT

An integrated circuit device includes a channel region, a gate line at least partially surrounding the channel region, the gate line having a first top surface extending in a first direction, wherein the first top surface of the gate line is a first distance apart from an uppermost surface of the channel region in a second direction perpendicular to the first direction, a source/drain region contacting the channel region, a source/drain contact located on the source/drain region and connected to the source/drain region, the source/drain contact having a second top surface coplanar with the first top surface of the gate line and extending in the first direction, and an etch stop insulating film extending from the first top surface of the gate line toward the second top surface of the source/drain contact in the first direction, the etch stop insulating film contacting the first top surface of the gate line.

### CROSS-REFERENCE TO RELATED APPLICATION

This application is based on and claims priority under 35 U.S.C. § 119 to Korean Patent Application No. 10-2024-0089118, filed on Jul. 5, 2024, in the Korean Intellectual Property Office, the disclosure of which is incorporated by reference herein in its entirety.

### BACKGROUND

The inventive concept relates to an integrated circuit (IC) device, and more particularly, to an IC device including a field-effect transistor (FET).

As the downscaling of IC devices is rapidly progressing, IC devices require having not only a high operating speed but also high operating accuracy. Accordingly, various studies are being conducted on developing an IC device having a structure that may provide optimum performance and may improve reliability.

### SUMMARY

The inventive concept provides an integrated circuit (IC) device having a structure capable of improving the electrical performance and reliability of a field-effect transistor (FET).

According to an aspect of the inventive concept, there is provided an IC device including a channel region, a gate line surrounding the channel region, the gate line having a first top surface extending in a first direction, wherein the first top surface of the gate line is a first distance apart from an uppermost surface of the channel region in a second direction perpendicular to the first direction, a source/drain region contacting the channel region, a source/drain contact located on the source/drain region and connected to the source/drain region, the source/drain contact having a second top surface coplanar with the first top surface of the gate line and extending in the first direction, and an etch stop insulating film extending from the first top surface of the gate line toward the second top surface of the source/drain contact in the first lateral direction, the etch stop insulating film contacting the first top surface of the gate line.

According to another aspect of the inventive concept, there is provided an IC device including a plurality of channel regions apart from each other in a first direction, a plurality of gate lines at least partially surrounding the plurality of channel regions, each gate line extending perpendicular to the plurality of channel regions, and each gate line having a first top surface extending in the first direction wherein the first top surface of the gate line is a first distance apart from of an uppermost surface of each of the plurality of channel regions in a second direction perpendicular to the first direction, a plurality of source/drain regions, each of the plurality of source/drain regions between two adjacent gate lines of the plurality of gate lines, a plurality of source/drain contacts, each of the plurality of source/drain contacts connected to a source/drain region of the plurality of source/drain regions, and each of the plurality of source/drain contacts having a second top surface coplanar with the first top surface of the gate line and extending in the first direction, and an etch stop insulating film extending in the first direction from the first top surface of each of the plurality of gate lines toward the second top surface of a source/drain contact, from among the plurality of source/drain contacts, the etch stop insulating film contacting the first top surface of each of the plurality of gate lines.

According to another aspect of the inventive concept, there is provided an IC device including a nanosheet stack comprising a plurality of nanosheets extending in a first direction and stacked in a second direction perpendicular to the first direction, a plurality of gate lines at least partially surrounding the plurality of nanosheets and extending lengthwise in a third direction perpendicular to the first direction and the second direction, a plurality of gate insulating spacers at least partially covering both sidewalls of each of the plurality of gate lines, a source/drain region between two adjacent ones of the plurality of gate lines, the source/drain region contacting the plurality of nanosheets, a source/drain contact on the source/drain region and connected to the source/drain region, an etch stop insulating film contacting a first top surface of each of the plurality of gate lines and a spacer top surface of each of the plurality of gate insulating spacers, a capping insulating film on a top surface of the etch stop insulating film, the capping insulating film including a different material from a constituent material of the etch stop insulating film, a plurality of gate contacts passing through the capping insulating film and the etch stop insulating film in the second direction, each gate contact contacting the first top surface of a corresponding one of the plurality of gate lines, and a via contact passing through the capping insulating film and the etch stop insulating film in the second direction and contacting a second top surface of the source/drain contact, wherein the first top surface of each of the plurality of gate lines and the second top surface of the source/drain contact are coplanar and extend in the first direction and the third direction, wherein the first top surface of each of the plurality of gate lines is a first distance apart from a an uppermost surface of the nanosheet stack in the second direction, and a third top surface of each of the plurality of gate contacts and a fourth top surface of the via contact are coplanar in the first direction, and are a second distance apart from the uppermost surface of the nanosheet stack in the second direction, and the second distance is greater than the first distance.

### BRIEF DESCRIPTION OF THE DRAWINGS

Embodiments will be more clearly understood from the following detailed description taken in conjunction with the accompanying drawings in which:

FIG. 1 is a schematic plan view of a cell block of an integrated circuit (IC) device according to embodiments;

FIG. 2 is a plan layout diagram of an IC device according to embodiments;

FIG. 3 is a cross-sectional view of the IC device taken along line X1-X1′ of FIG. 2;

FIG. 4 is a cross-sectional view of the IC device taken along line Y1-Y1′ of FIG. 2;

FIG. 5 is a cross-sectional view of the IC device taken along line Y2-Y2′ of FIG. 2;

FIG. 6 is an enlarged cross-sectional view of a region indicated by “EX1” of FIG. 3;

FIG. 7 is a cross-sectional view of an IC device according to embodiments;

FIGS. 8A and 8B are cross-sectional views of an IC device according to embodiments;

FIGS. 9A, 9B, 10A, 10B, 11A, 11B, 12A, 12B, 12C, 13A, 13B, 13C, 14A, 14B, 15A, 15B, 16A, 16B, 17, 18, 19, 20, 21, 22, 23, 24, 25, 26, 27, and 28 are cross-sectional views showing a process sequence of a method of manufacturing an IC device, according to embodiments, wherein FIGS. 9A, 10A, 11A, 12A, 13A, 14A, 15A, 16A, and 17 to 28 are cross-sectional views showing example cross-sectional structures of a portion corresponding to a cross-section taken along line X1-X1′ of FIG. 2, according to the process sequence, FIGS. 9B, 10B, 11B, 12B, 13B, 14B, 15B, and 16B are cross-sectional views showing example cross-sectional structures of a portion corresponding to a cross-section taken along line Y1-Y1′ of FIG. 2, according to the process sequence, and FIGS. 12C and 13C are cross-sectional views showing example cross-sectional structures of a portion corresponding to a cross-section taken along line Y2-Y2′ of FIG. 2, according to the process sequence;

FIGS. 29 to 35 are cross-sectional views showing a process sequence of a method of manufacturing an IC device, according to embodiments; and

FIGS. 36A, 36B, 37A, 37B, 38A, 38B, 39, 40, 41, and 42 are cross-sectional views showing a process sequence of a method of manufacturing an IC device, according to embodiments, wherein FIGS. 36A, 37A, 38A, and 39 to 42 are cross-sectional views showing example cross-sectional structures of a portion corresponding to a cross-section taken along line X1-X1′ of FIG. 2, according to the process sequence, and FIGS. 36B, 37B, and 38B are cross-sectional views showing example cross-sectional structures of a portion corresponding to a cross-section taken along line Y1-Y1′ of FIG. 2, according to the process sequence.

### DETAILED DESCRIPTION OF THE EMBODIMENTS

Hereinafter, embodiments will be described in detail with reference to the accompanying drawings. The same reference numerals are used to denote the same elements in the drawings, and repeated descriptions thereof will be omitted.

The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

Components or layers described with reference to “overlap” in a particular direction may be at least partially obstructed by one another when viewed along a line extending in the particular direction or in a plane perpendicular to the particular direction. The term “surrounding” or “covering” or “filling” as may be used herein may not require completely surrounding or covering or filling the described elements or layers, but may, for example, refer to partially surrounding or covering or filling the described elements or layers, for example, with voids or other spaces throughout. The term “exposed,” may be used to describe relationships between elements and/or certain intermediate processes in fabricating a completed semiconductor device but may not necessarily require exposure of the particular region, layer, structure or other element in the context of the completed device.

It will be understood that spatially relative terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

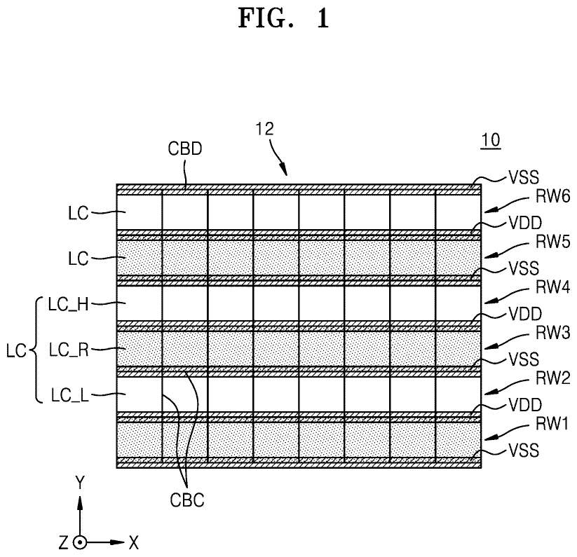

FIG. 1 is a schematic plan view of a cell block 12 of an integrated circuit (IC) device 10 according to embodiments.

Referring to FIG. 1, the cell block 12 of the IC device 10 may include a plurality of cells LC, which include circuit patterns configured to constitute various circuits. The plurality of cells LC may be arranged in a matrix form in a widthwise direction (X direction in FIG. 1) and a height direction (Y direction in FIG. 1) in the cell block 12.

Each of the plurality of cells LC may include a circuit pattern having a layout designed according to a place-and-route (PnR) technique to perform at least one logic function. The plurality of cells LC may perform various logic functions. In embodiments, the plurality of cells LC may include a plurality of standard cells. In embodiments, at least some of the plurality of cells LC may perform the same logic function. In other embodiments, at least some of the plurality of cells LC may perform different logic functions.

The plurality of cells LC may include various kinds of logic cells including a plurality of circuit elements. For example, each of the plurality of logic cells LC may include an AND, a NAND, an OR, a NOR, an exclusive OR (XOR), an exclusive NOR (XNOR), an inverter (INV), an adder (ADD), a buffer (BUF), a delay (DLY), a filter (FIL), a multiplexer (MXT/MXIT), an OR/AND/INVERTER (OAI), an AND/OR (AO), an AND/OR/INVERTER (AOI), a D-flip-flop, a reset flip-flop, a master-slave flip-flop, a latch, or a combination thereof, without being limited thereto.

In the cell block 12, at least some of the plurality of cells LC that form one row RW1, RW2, RW3, RW4, RW5, or RW6 in the widthwise direction (X direction in FIG. 1) may have the same width as each other. Also, at least some of the plurality of cells LC that form one row RW1, RW2, RW3, RW4, RW5, or RW6 may have the same height as each other. However, the inventive concept is not limited to those illustrated in FIG. 1, and at least some of the plurality of cells LC that form one row RW1, RW2, RW3, RW4, RW5, or RW6 may have different widths and heights from each other.

An area of each of the plurality of cells LC included in the cell block 12 of the IC device 10 may be defined by a cell boundary CBD. A cell boundary contact portion CBC where respective cell boundaries CBD of two cells LC that are adjacent to each other in the widthwise direction (X direction in FIG. 1) or the height direction (Y direction in FIG. 1), from among the plurality of cells LC, meet each other may be between the two adjacent cells LC.

In embodiments, from among the plurality of cells LC that form one row RW1, RW2, RW3, RW4, RW5, or RW6, two cells LC that are adjacent to each other in the widthwise direction may contact each other at the cell boundary contact portion CBC without a distance therebetween. In other embodiments, from among the plurality of cells LC that form one row RW1, RW2, RW3, RW4, RW5, or RW6, two cells LC that are adjacent to each other in the widthwise direction may be a predetermined distance apart from each other.

In embodiments, from among the plurality of cells LC that form one row RW1, RW2, RW3, RW4, RW5, or RW6, two adjacent cells LC may perform the same function as each other. In this case, the two adjacent cells LC may have the same structure as each other. In other embodiments, from among the plurality of cells LC that form one row RW1, RW2, RW3, RW4, RW5, or RW6, two adjacent cells may perform different functions from each other.

In embodiments, one cell LC, which is selected from the plurality of cells LC included in the cell block 12 of the IC device 10, may have a symmetrical structure to another cell LC, which is adjacent to the selected cell LC in the height direction (Y direction in FIG. 1), about the cell boundary contact portion CBC therebetween. For example, a reference cell LC_R in a third row RW3 may have a symmetrical structure to a lower cell LC_L in a second row RW2 about the cell boundary contact portion CBC therebetween. Also, the reference cell LC_R in the third row RW3 may have a symmetrical structure to an upper cell LC_H in a fourth row RW4 about the cell boundary contact portion CBC therebetween. Although FIG. 1 illustrates an example in which the cell block 12 includes six rows RW1, RW2, . . . , and RW6, the inventive concept is not limited thereto. The cell block 12 may include various numbers of rows, which are selected as needed, and one row may include various numbers of cells, which are selected as needed.

A selected one of a plurality of ground lines VSS and a plurality of power lines VDD may be between a plurality of rows (e.g., RW1, RW2, RW3, RW4, RW5, and RW6), each of which includes a plurality of cells LC arranged in a line in the widthwise direction (X direction in FIG. 1). The plurality of ground lines VSS and the plurality of power lines VDD may each extend in the widthwise direction (X direction) and may be alternately arranged apart from each other in the height direction (Y direction). The second lateral direction (Y direction) may be perpendicular to the first lateral direction (X direction). Accordingly, the plurality of ground lines VSS and the plurality of power lines VDD may each overlap the cell boundary CBD of the cell LC in the second lateral direction (Y direction).

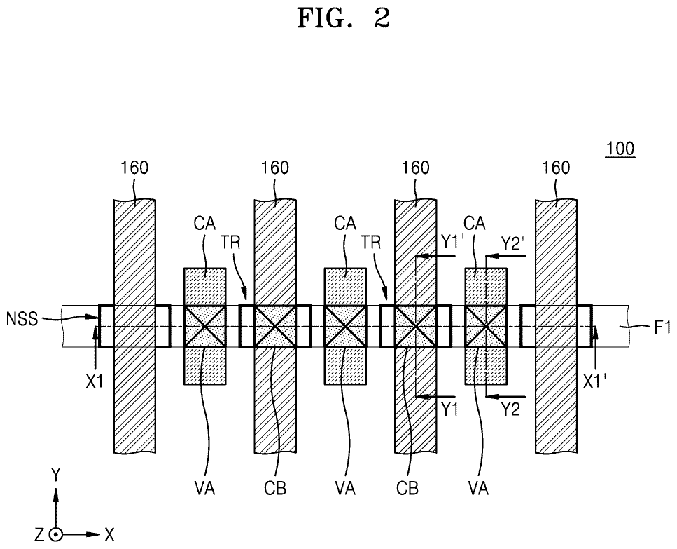

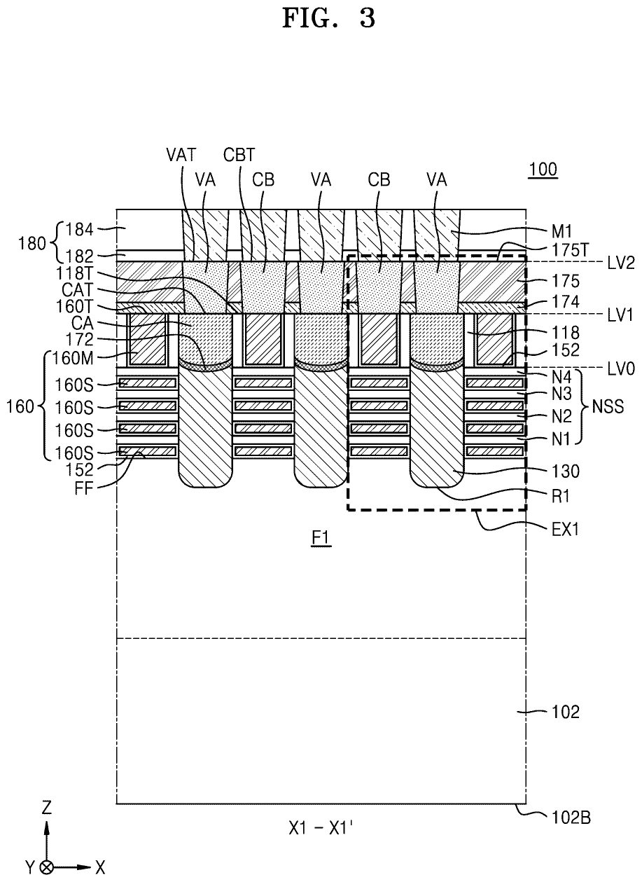

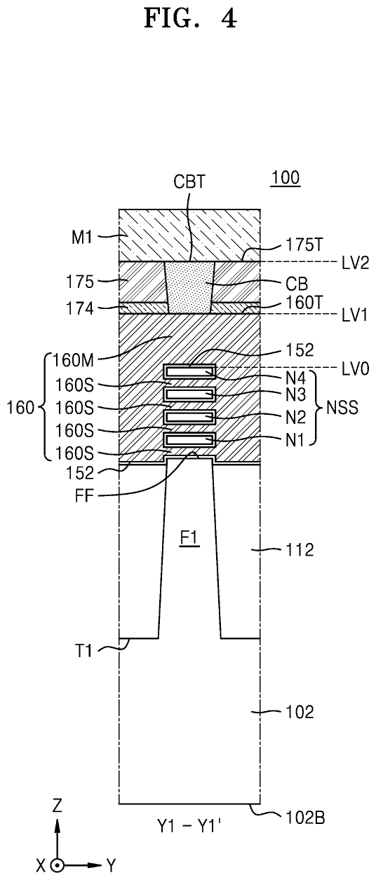

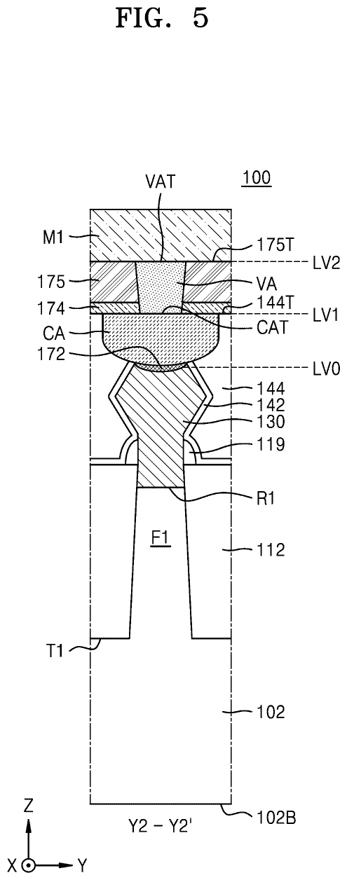

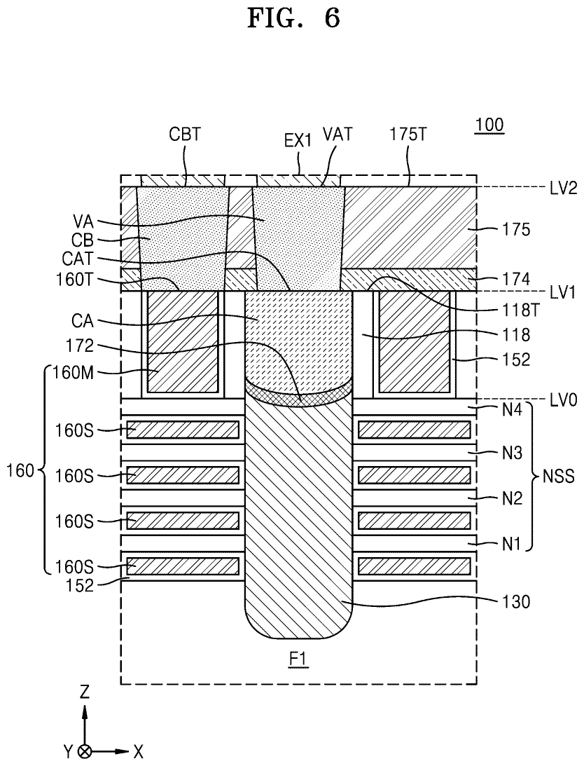

FIG. 2 is a plan layout diagram of an IC device 100 according to embodiments. FIG. 3 is a cross-sectional view of the IC device 100 taken along line X1-X1′ of FIG. 2. FIG. 4 is a cross-sectional view of the IC device 100 taken along line Y1-Y1′ of FIG. 2. FIG. 5 is a cross-sectional view of the IC device 100 taken along line Y2-Y2′ of FIG. 2. FIG. 6 is an enlarged cross-sectional view of a region indicated by “EX1” of FIG. 3. The IC device 100 including a field-effect transistor (FET) having a gate-all-around structure including a channel region of a nanowire or nanosheet type and a gate surrounding the channel region is described with reference to FIGS. 2 to 6. Components of the IC device 100, which are described with reference to FIGS. 2 to 6, may constitute some of the plurality of cells LC shown in FIG. 1.

Referring to FIGS. 2 to 6, the IC device 100 may include a fin-type active region F1, a plurality of nanosheet stacks NSS, a plurality of gate lines 160, and a plurality of source/drain regions 130. The fin-type active region F1 may protrude from a substrate 102 and extend lengthwise in a first lateral direction (X direction). The plurality of nanosheet stacks NSS may be apart upward from the fin-type active region F1 in a vertical direction (Z direction) and face a fin top surface FF of the fin-type active region F1. The plurality of gate lines 160 may surround the plurality of nanosheet stacks NSS. Each of the plurality of source/drain regions 130 may be between two adjacent ones of the plurality of gate lines 160. Each of the plurality of gate lines 160 may be surrounded by a gate dielectric film 152. The plurality of gate lines 160, the plurality of nanosheet stacks NSS, and the plurality of source/drain regions 130 may constitute a plurality of FETs TR.

As used herein, the term “nanosheet” refers to a conductive structure having a cross-section that is substantially perpendicular to a direction in which current flows. The nanosheet may be interpreted as including a nanowire. The substrate 102 may include an element semiconductor, such as silicon (Si) or germanium (Ge), or a compound semiconductor, such as silicon germanium (SiGe), silicon carbide (SiC), gallium arsenide (GaAs), indium arsenide (InAs), indium gallium arsenide (InGaAs), or indium phosphide (InP). As used herein, each of the terms “SiGe,” “SiC,” “GaAs,” “InAs,” “InGaAs,” and “InP” refers to a material including elements included therein, without referring to a chemical formula representing a stoichiometric relationship. The substrate 102 may include a conductive region, for example, a doped well or a doped structure.

A trench T1 defining the fin-type active region F1 may be formed in the substrate 102. The trench T1 may be filled by a field insulating film 112. The field insulating film 112 may include a silicon oxide film. A plurality of gate lines 160 may be on the fin-type active region F1. Each of the plurality of gate lines 160 may extend lengthwise in a second lateral direction (Y direction), which is perpendicular to the first lateral direction (X direction). The plurality of nanosheet stacks NSS may be respectively on fin top surfaces FF of the plurality of fin-type active regions F1 in regions where the plurality of fin-type active regions F1 intersect the plurality of gate lines 160. Each of the plurality of nanosheet stacks NSS may include at least one nanosheet. As shown in FIGS. 3, 4, and 6, each of the plurality of nanosheet stacks NSS may include first to fourth nanosheets N1, N2, N3, and N4, which overlap each other in the vertical direction (Z direction) on the fin-type active region F1. Each of the first to fourth nanosheets N1, N2, N3, and N4 included in the nanosheet stack NSS may provide a channel region. As used herein, the nanosheet stacks NSS, each of which includes the first to fourth nanosheets N1, N2, N3, and N4, may be each referred to as a channel region.

In embodiments, each of the first to fourth nanosheets N1, N2, N3, and N4 included in the nanosheet stack NSS may include a Si layer, a SiGe layer, or a combination thereof. For example, each of the first to fourth nanosheets N1, N2, N3, and N4 may include a Si layer.

The first to fourth nanosheets N1, N2, N3, and N4 may be at different vertical distances (Z-direction distances) from the fin top surface FF of the fin-type active region F1. Each of the plurality of gate lines 160 may surround the first to fourth nanosheets N1, N2, N3, and N4, which are included in the nanosheet stack NSS and overlap each other in the vertical direction (Z direction).

Although FIG. 2 illustrates a case in which the nanosheet stack NSS has a substantially rectangular planar shape, the inventive concept is not limited thereto. The nanosheet stack NSS may have various planar shapes according to a planar shape of each of the fin-type active region F1 and the gate line 160. The present embodiment pertains to a configuration in which the plurality of nanosheet stacks NSS and the plurality of gate lines 160 are formed on one fin-type active region F1, and the plurality of nanosheet stacks NSS are arranged in a line in the first lateral direction (X direction) on one fin-type active region F1. However, the number of nanosheet stacks NSS and the number of gate lines 160 on one fin-type active region F1 are not specifically limited and may be variously changed as needed. FIGS. 3, 4, and 6 illustrate an example in which each of the plurality of nanosheet stacks NSS includes the first to fourth nanosheets N1, N2, N3, and N4, but the inventive concept is not limited thereto. For example, the nanosheet stack NSS may include at least one nanosheet, and the number of nanosheets in the nanosheet stack NSS is not specifically limited.

In embodiments, each of the first to fourth nanosheets N1, N2, N3, and N4 may have a thickness selected in a range of about 4 nm to about 6 nm, without being limited thereto. Here, the thickness of each of the first to fourth nanosheets N1, N2, N3, and N4 refers to a size of each of the first to third nanosheets N1, N2, N3, and N4 in the vertical direction (Z direction). In embodiments, the first to fourth nanosheets N1, N2, N3, and N4 may have substantially the same thickness in the vertical direction (Z direction). In other embodiments, at least some of the first to fourth nanosheets N1, N2, N3, and N4 may have different thicknesses in the vertical direction (Z direction).

As shown in FIGS. 3 and 6, the first to third nanosheets N1, N2, N3, and N4 included in one nanosheet stack NSS may have the same size or similar sizes in the first lateral direction (X direction). In other embodiments, differently from that shown in FIGS. 3 and 6, at least some of the first to third nanosheets N1, N2, N3, and N4 included in one nanosheet stack NSS may have different sizes in the first lateral direction (X direction).

As shown in FIGS. 3, 4, and 6, each of the plurality of gate lines 160 may include a main gate portion 160M and a plurality of sub-gate portions 160S. The main gate portion 160M may cover a top surface of the nanosheet stack NSS and extend lengthwise in the second lateral direction (Y direction). The plurality of sub-gate portions 160S may be integrally connected to the main gate portion 160M and respectively one-by-one arranged between the first to fourth nanosheets N1, N2, N3, and N4 and between the first nanosheet N1 and a fin top surface FF of the fin-type active region F1. In the vertical direction (Z direction), a thickness of each of the plurality of sub-gate portions 160S may be less than a thickness of the main gate portion 160M.

The plurality of gate lines 160 may include a metal, a metal nitride, a metal carbide, or a combination thereof. The metal may be selected from molybdenum (Mo), ruthenium (Ru), copper (Cu), and tungsten (W). The metal nitride may be selected from titanium nitride (TiN), tantalum nitride (TaN), and titanium aluminum nitride (TiAIN), or a combination thereof. The metal carbide may include titanium aluminum carbide (TiAIC). However, a material included in the plurality of gate lines 160 is not limited to the examples described above.

As shown in FIG. 4, the field insulating film 112 may be between the substrate 102 and the gate line 160 in the vertical direction (Z direction). The field insulating film 112 may cover a sidewall of the fin-type active region F1 in the second lateral direction (Y direction).

As shown in FIGS. 3 and 5, a plurality of recesses R1 may be formed in the fin-type active region F1. A lowermost surface of each of the plurality of recesses R1 may be at a lower vertical level than the fin top surface FF of the fin-type active region F1.

A plurality of source/drain regions 130 may be inside the plurality of recesses R1. Each of the plurality of source/drain regions 130 may be adjacent to at least one gate line 160 selected from the plurality of gate lines 160. Each of the plurality of source/drain regions 130 may have surfaces in contact with the first to fourth nanosheets N1, N2, N3, and N4 included in the nanosheet stack NSS adjacent thereto.

Each of the plurality of source/drain regions 130 may include an epitaxially grown semiconductor layer. In embodiments, each of the plurality of source/drain regions 130 may include an epitaxially grown Si layer, an epitaxially grown SiC layer, or a plurality of epitaxially grown SiGe layers. When the source/drain region 130 constitutes an NMOS transistor, the source/drain region 130 may include a Si layer doped with an n-type dopant or a SiC layer doped with an n-type dopant. The n-type dopant may be selected from phosphorus (P), arsenic (As), and antimony (Sb). When the source/drain region 130 constitutes a PMOS transistor, the source/drain region 130 may include a SiGe layer doped with a p-type dopant. The p-type dopant may be selected from boron (B) and gallium (Ga).

Each of the plurality of gate lines 160 may have a first top surface 160T, which extends at a first vertical level LV1 in a lateral direction (e.g., the first lateral direction (X direction) and the second lateral direction (Y direction)). The first vertical level LV1 may be a first distance apart from a reference vertical level LV0 in the vertical direction (Z direction), and the reference vertical level LV0 may be a vertical level of an uppermost surface of the nanosheet stack NSS. The first distance may be a shortest distance between the reference vertical level LV0 and the first vertical level LV1. In FIGS. 3 to 6, the uppermost surface of the nanosheet stack NSS may correspond to a top surface of the fourth nanosheet N4.

As shown in FIGS. 3 and 6, both sidewalls of each of the plurality of gate lines 160 in the first lateral direction (X direction) may be covered by gate insulating spacers 118. Each of a plurality of gate insulating spacers 118 included in the IC device 100 may extend lengthwise along with the gate line 160 in the second lateral direction (Y direction) on the nanosheet stack NSS and the field insulating film 112. The gate insulating spacers 118 may cover both sidewalls of the main gate portion 160M on the top surface of each of the plurality of nanosheet stacks NSS. The gate insulating spacer 118 may be apart from the gate line 160 with the gate dielectric film 152 therebetween. The gate insulating spacers 118 may each include silicon nitride, silicon oxide, silicon carbonitride (SiCN), silicon boron nitride (SiBN), silicon oxynitride (SiON), silicon oxycarbonitride (SiOCN), silicon boron carbonitride (SiBCN), silicon oxycarbide (SiOC), or a combination thereof. As used herein, each of the terms “SiCN,” “SiBN,” “SiON,” “SiOCN,” “SiBCN,” and “SiOC” refers to a material including elements included therein, without referring to a chemical formula representing a stoichiometric relationship.

A gate dielectric film 152 may be between the nanosheet stack NSS and the gate line 160. The gate dielectric film 152 may have a stack structure of an interface dielectric film and a high-k dielectric film. The interface dielectric film may include a low-k dielectric material film (e.g., a silicon oxide film, a silicon oxynitride film, or a combination thereof), which has a dielectric constant of about 9 or less. In embodiments, the interface dielectric film may be omitted. The high-k dielectric film may include a material having a higher dielectric constant than a silicon oxide film. For example, the high-k dielectric film may have a dielectric constant of about 10 to 25. The high-k dielectric film may include hafnium oxide, without being limited thereto.

Both sidewalls of each of the plurality of sub-gate portions 160S included in the plurality of gate lines 160 may be apart from the source/drain region 130 with the gate dielectric film 152 therebetween. The gate dielectric film 152 may include respective portions between the sub-gate portion 160S included in the gate line 160 and the first to fourth nanosheets N1, N2, N3, and N4, portions between the sub-gate portion 160S included in the gate line 160 and the source/drain region 130, and a portion between the fin top surface FF of the fin-type active region F1 and the sub-gate portion 160S that is closest to the fin top surface FF of the fin-type active region F1, from among the plurality of sub-gate portions 160S included in the gate line 160.

A metal silicide film 172 may be formed on a top surface of each of the plurality of source/drain regions 130. The metal silicide film 172 may include a metal, which includes titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), or palladium (Pd). For example, the metal silicide film 172 may include titanium silicide, without being limited thereto.

As shown in FIG. 5, an insulating liner 142 and an inter-gate dielectric film 144 may be sequentially located on the plurality of source/drain regions 130. The insulating liner 142 and the inter-gate dielectric film 144 may constitute an inter-gate insulating structure. The plurality of source/drain regions 130 may be covered by the insulating liner 142. In embodiments, the insulating liner 142 may include silicon nitride (SiN), SiCN, SiBN, SION, SiOCN, SiBCN, or a combination thereof, without being limited thereto. The inter-gate dielectric film 144 may include a silicon oxide film, without being limited thereto.

As shown in FIG. 5, the field insulating film 112 may have a top surface contacting the insulating liner 142. A plurality of side insulating spacers 119 may be on the field insulating film 112 on both sides of the source/drain region 130 in the second lateral direction (Y direction). Each of the plurality of side insulating spacers 119 may cover a sidewall of a partial region of the source/drain region 130, which is adjacent to the fin-type active region F1. Each of the plurality of side insulating spacers 119 may be in contact with a sidewall of the source/drain region 130. The plurality of side insulating spacers 119 may be covered by the insulating liner 142. Each of the plurality of side insulating spacers 119 may include the same material as a constituent material of the gate insulating spacer 118. In other embodiments, at least some of the plurality of side insulating spacers 119 may be omitted.

As shown in FIGS. 3, 5, and 6, a plurality of source/drain contacts CA may be on the plurality of source/drain regions 130. Each of the plurality of source/drain contacts CA may pass through an inter-gate dielectric structure including the inter-gate dielectric film 144 and the insulating liner 142 in the vertical direction (Z direction) and be electrically connected to one source/drain region 130 selected from the plurality of source/drain regions 130. A bottom surface of each of the plurality of source/drain contacts CA may be in contact with a metal silicide film 172 formed on the source/drain region 130. The metal silicide film 172 may be between the source/drain region 130 and the source/drain contact CA.

Each of the plurality of source/drain contacts CA may be electrically connectable to the source/drain region 130 through the metal silicide film 172. Each of the plurality of source/drain contacts CA may be apart from the main gate portion 160M of the gate line 160 with the gate insulating spacer 118 therebetween in the first lateral direction (X direction).

In embodiments, each of the plurality of source/drain contact CA may include a metal plug and a conductive barrier film surrounding the metal plug. The metal plug may include molybdenum (Mo), tungsten (W), cobalt (Co), ruthenium (Ru), manganese (Mn), titanium (Ti), tantalum (Ta), aluminum (AI), copper (Cu), a combination thereof, or an alloy thereof, without being limited thereto. The conductive barrier film may include a metal or a conductive metal nitride. For example, the conductive barrier film may include titanium (Ti), tantalum (Ta), tungsten (W), titanium nitride (TiN), tantalum nitride (TaN), tungsten nitride (WN), tungsten carbonitride (WCN), titanium silicon nitride (TiSiN), tantalum silicon nitride (TaSiN), tungsten silicon nitride (WSiN), or a combination thereof, without being limited thereto. In other embodiments, the conductive barrier film may be omitted in each of the plurality of source/drain contacts CA.

Each of the plurality of source/drain contacts CA may have a second top surface CAT, which extends at the first vertical level LV1 in a lateral direction (e.g., the first lateral direction (X direction) and the second lateral direction (Y direction)). In addition, each of the plurality of gate insulating spacers 118 may have a spacer top surface 118T, which extends at the first vertical level LV1 in a lateral direction (e.g., the first lateral direction (X direction) and the second lateral direction (Y direction)). That is, the first top surface 160T of each of the plurality of gate lines 160, the second top surface CAT of each of the plurality of source/drain contacts CA, and the spacer top surface 118T of each of the plurality of gate insulating spacers 118 may extend at the same vertical level in a lateral direction (e.g., the first lateral direction (X direction) and the second lateral direction (Y direction)).

The first top surface 160T of each of the plurality of gate lines 160, an uppermost surface of the gate dielectric film 152, the second top surface CAT of each of the plurality of source/drain contacts CA, and the spacer top surface 118T of each of the plurality of gate insulating spacers 118 may be covered by an etch stop insulating film 174. The first top surface 160T of each of the plurality of gate lines 160, the uppermost surface of the gate dielectric film 152, the second top surface CAT of each of the plurality of source/drain contacts CA, and the spacer top surface 118T of each of the plurality of gate insulating spacers 118 may be in contact with a bottom surface of the etch stop insulating film 174.

The etch stop insulating film 174 may extend in the first lateral direction (X direction) from the first top surface 160T of each of the plurality of gate lines 160 toward the second top surface CAT of the source/drain contact CA adjacent to the etch stop insulating film 174, from among the plurality of source/drain contacts CA.

As shown in FIG. 5, in the second lateral direction (Y direction), the inter-gate dielectric film 144 may cover a sidewall of each of the source/drain region 130 and the source/drain contact CA. An insulating top surface 144T of the inter-gate dielectric film 144 may extend at the first vertical level LV1 in a lateral direction (e.g., the first lateral direction (X direction) and the second lateral direction (Y direction)). The insulating top surface 144T of the inter-gate dielectric film 144 may be in contact with the bottom surface of the etch stop insulating film 174.

A capping insulating film 175 may be on the etch stop insulating film 174. A bottom surface of the capping insulating film 175 may be in contact with a top surface of the etch stop insulating film 174.

The etch stop insulating film 174 and the capping insulating film 175 may include different insulating materials from each other. For example, the etch stop insulating film 174 may include a silicon oxide film or an aluminum oxide film, and the capping insulating film 175 may include a silicon nitride film. In embodiments, the etch stop insulating film 174 may include a single film including a single material, which is selected from a silicon oxide film and an aluminum oxide film.

The IC device 100 may further include a plurality of gate contacts CB contacting the first top surfaces 160T of the plurality of gate lines 160 and a plurality of via contacts VA contacting the second top surfaces CAT of the plurality of source/drain contacts CA.

Each of the plurality of gate contacts CB and the plurality of via contacts VA may pass through the capping insulating film 175 and the etch stop insulating film 174 in the vertical direction (Z direction). The capping insulating film 175 and the etch stop insulating film 174 may surround a sidewall of each of the plurality of gate contacts CB and the plurality of via contacts VA.

Each of the plurality of gate contacts CB may have a third top surface CBT, and each of the plurality of via contacts VA may have a fourth top surface VAT. The third top surface CBT of each of the plurality of gate contacts CB and the fourth top surface VAT of each of the plurality of via contacts VA may extend at a second vertical level LV2 in a lateral direction (e.g., the first lateral direction (X direction) and the second lateral direction (Y direction)). The second vertical level LV2 may be a second distance apart from the reference vertical level LV0 in the vertical direction (Z direction). The second distance may be a shortest distance between the reference vertical level LV0 and the second vertical level LV2. The second distance may be greater than the first distance, which is the shortest distance between the reference vertical level LV0 and the first vertical level LV1.

Each of the plurality of gate contacts CB and the plurality of via contacts VA may include a metal plug and a conductive barrier film surrounding the metal plug. The meal plug included in each of the plurality of gate contacts CB may include molybdenum (Mo), tungsten (W), cobalt (Co), ruthenium (Ru), manganese (Mn), titanium (Ti), tantalum (Ta), aluminum (AI), copper (Cu), a combination thereof, or an alloy thereof, without being limited thereto. The conductive barrier film included in each of the plurality of gate contacts CB and the plurality of via contacts VA may include a metal or a conductive metal nitride. For example, the conductive barrier film may include Ti, Ta, W, TiN, TaN, WN, WCN, TiSiN, TaSiN, WSiN, or a combination thereof, without being limited thereto. In other embodiments, the conductive barrier film may be omitted in each of the plurality of gate contacts CB and the plurality of via contacts VA.

The capping insulating film 175 may have a capping top surface 175T, which extends at the second vertical level LV2 in a lateral direction (e.g., the first lateral direction (X direction) and the second lateral direction (Y direction)). The capping top surface 175T of the capping insulating film 175, the third top surface CBT of each of the plurality of gate contacts CB, and the fourth top surface VAT of each of the plurality of via contacts VA may extend at the same vertical level in a lateral direction (e.g., the first lateral direction (X direction) and the second lateral direction (Y direction)).

As shown in FIG. 3, the fin-type active region F1 may be in contact with a bottom surface of each of the plurality of source/drain regions 130. The bottom surface of each of the plurality of source/drain regions 130 may be a surface of each of the plurality of source/drain regions 130, which is closest to a backside surface 102B of the substrate 102. The fin-type active region F1 may be apart from the etch stop insulating film 174 with the plurality of source/drain regions 130 therebetween in the vertical direction (Z direction).

The third top surface CBT of each of the plurality of gate contacts CB, the fourth top surface VAT of each of the plurality of via contacts VA, and the capping top surface 175T of the capping insulating film 175 may be covered by an upper insulating structure 180. The upper insulating structure 180 may include an etch stop film 182 and an upper insulating film 184, which are sequentially stacked on each of the plurality of gate contacts CB, the plurality of via contacts VA, and the capping insulating film 175. The etch stop film 182 may include silicon carbide (SiC), silicon nitride (SiN), silicon carbonitride (SiCN), silicon oxycarbide (SiOC), aluminum nitride (AlN), aluminum oxynitride (AlON), aluminum oxide (AlO), aluminum oxycarbide (AlOC), or a combination thereof. The upper insulating film 184 may include an oxide film, a nitride film, an ultralow-k (ULK) film having an ultralow dielectric constant of about 2.2 to about 2.4, or a combination thereof. For example, the upper insulating film 184 may include a tetraethylorthosilicate (TEOS) film, a high-density plasma (HDP) film, a boro-phospho-silicate glass (BPSG) film, a flowable chemical vapor deposition (FCVD) oxide film, a silicon oxynitride (SiON) film, a silicon nitride (SiN) film, a silicon oxycarbide (SiOC) film, a SiCOH film, or a combination thereof, without being limited thereto.

The plurality of upper wiring layers M1 may pass through the upper insulating structure 180. Each of the plurality of upper wiring layers M1 may be connected to the plurality of via contacts VA or the gate contact CB. The plurality of upper wiring layers M1 may include molybdenum (Mo), copper (Cu), tungsten (W), cobalt (Co), ruthenium (Ru), manganese (Mn), titanium (Ti), tantalum (Ta), aluminum (AI), a combination thereof, or an alloy thereof, without being limited thereto.

When necessary, the IC device 100 may further include a back-end-of-line (BEOL) structure including a plurality of wirings on the upper insulating structure 180 and the plurality of upper wiring layers M1.

To improve electrical properties of the FET TR, the IC device 100 described with reference to FIGS. 2 to 6 may have a structure in which the top surface of the source/drain contact CA and the top surface of the gate line 160 extend at the same vertical level in the lateral direction. In addition, the third top surface CBT of the gate contact CB connected to the gate line 160 and the fourth top surface VAT of the via contact VA connected to the source/drain contact CA may extend at the same vertical level in the lateral direction (e.g., the first lateral direction (X direction) and the second lateral direction (Y direction)). Furthermore, portions of the first top surface 160T of the gate line 160, except for a portion connected to the gate contact CB, and the spacer top surfaces 118T of the gate insulating spacers 118 covering both sidewalls of the gate line 160 may extend at the same vertical level and each contact the etch stop insulating film 174. The etch stop insulating film 174 may have a structure extending in the first lateral direction (X direction) from the first top surface 160T of the gate line 160 toward the second top surface CAT of the source/drain contact CA. Accordingly, a length of the gate line 160 in the vertical direction (Z direction) may be reduced, and thus, a capacitance of the gate line 160 may be reduced. Also, a length of each of the source/drain contact CA, the via contact VA, and the gate contact CB in the vertical direction (Z direction) may be reduced, and thus, a contact resistance of each contact structure including the source/drain contact CA, the via contact VA, and the gate contact CB may be reduced. Also, an insulating margin may be ensured to prevent the occurrence of short circuits between the contact structure and conductive structures adjacent thereto. Therefore, the IC device 100 according to the inventive concept may improve the electrical performance and reliability of the FETs TR.

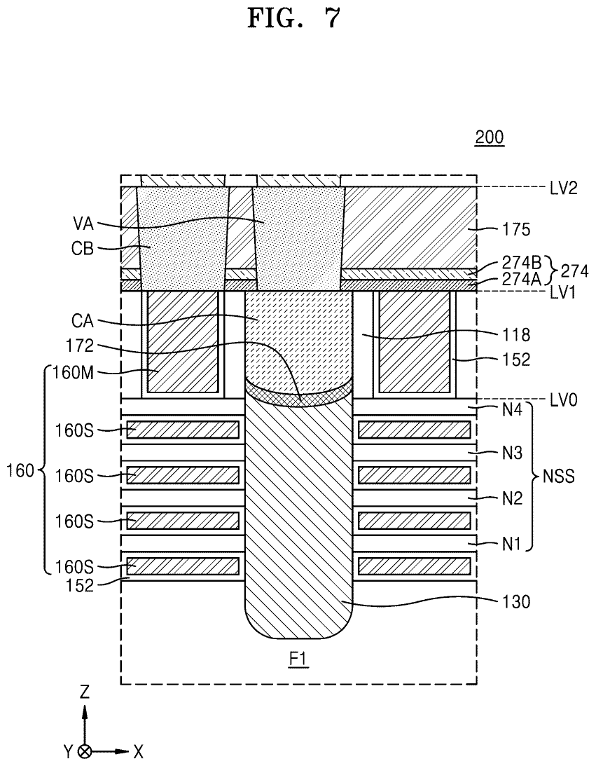

FIG. 7 is a cross-sectional view of an IC device 200 according to embodiments. FIG. 7 illustrates a cross-sectional configuration of a portion corresponding to a cross-section taken along line X1-X1′ of FIG. 2, in the IC device 200. In FIG. 7, the same reference numerals are used to denote the same elements as in FIGS. 2 to 6, and detailed descriptions thereof are omitted. Components of the IC device 200 described with reference to FIG. 7 may constitute some of the plurality of cells LC shown in FIG. 1.

Referring to FIG. 7, the IC device 200 may substantially have the same configuration as the IC device 100 described with reference to FIGS. 2 to 6. However, the IC device 200 shown in FIG. 7 may include an etch stop insulating film 274.

The etch stop insulating film 274 may substantially have the same configuration as the etch stop insulating film 174 described with reference to FIGS. 3 to 6. However, the etch stop insulating film 274 may have a double layer structure including a first etch stop insulating film 274A and a second etch stop insulating film 274B, which are sequentially stacked on a first top surface 160T of each of the plurality of gate lines 160, an uppermost surface of a gate dielectric film 152, a second top surface CAT of each of the plurality of source/drain contacts CA, and a spacer top surface 118T of each of the plurality of gate insulating spacers 118. A bottom surface of the first etch stop insulating film 274A may be in contact with each of the first top surface 160T of each of the plurality of gate lines 160, the uppermost surface of the gate dielectric film 152, the second top surface CAT of each of the plurality of source/drain contacts CA, and the spacer top surface 118T of each of the plurality of gate insulating spacers 118.

The etch stop insulating film 274 may include a combination of a silicon oxide film and an aluminum oxide film, and the first etch stop insulating film 274A and the second etch stop insulating film 274B may include different films, each of which is selected from a silicon oxide film and an aluminum oxide film. In embodiments, the first etch stop insulating film 274A may include a silicon oxide film, and the second etch stop insulating film 274B may include an aluminum oxide film. In other embodiments, the first etch stop insulating film 274A may include an aluminum oxide film, and the second etch stop insulating film 274B may include a silicon oxide film.

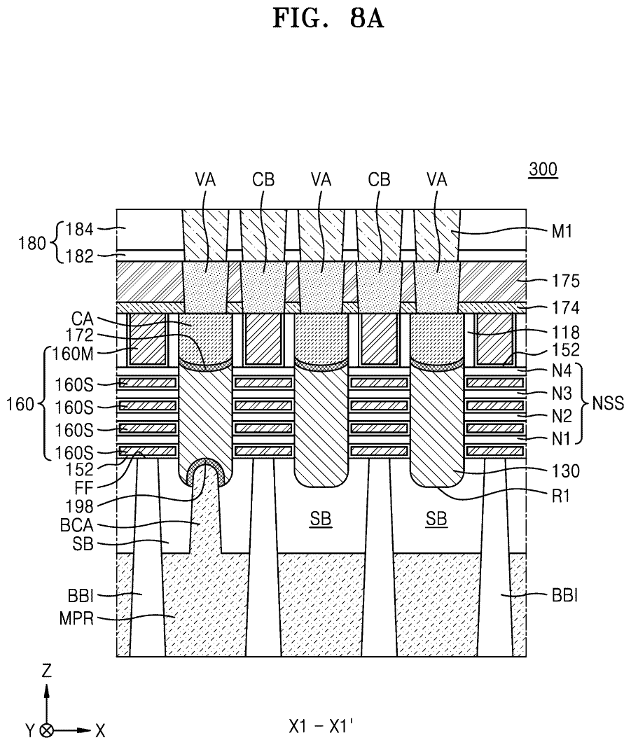

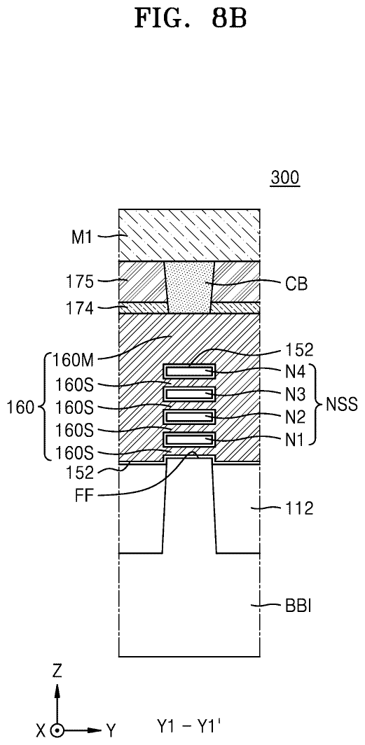

FIGS. 8A and 8B are cross-sectional views of an IC device 300 according to embodiments. FIG. 8A illustrates a cross-sectional configuration of a portion corresponding to a cross-section taken along line X1-X1′ of FIG. 2, in the IC device 300, and FIG. 8B illustrates a cross-sectional configuration of a portion corresponding to a cross-section taken along line Y1-Y1′ of FIG. 2, in the IC device 300. In FIGS. 8A and 8B, the same reference numerals are used to denote the same elements as in FIGS. 2 to 6, and detailed descriptions thereof are omitted. Components of the IC device 300 described with reference to FIGS. 8A and 8B may constitute some of the plurality of cells LC shown in FIG. 1.

Referring to FIGS. 8A and 8B, the IC device 200 may substantially have the same configuration as the IC device 100 described with reference to FIGS. 2 to 6. However, the IC device 300 may include a backside source/drain contact BCA and a backside power rail MPR connected to the backside source/drain contact BCA.

The backside source/drain contact BCA may be configured to be connected to one source/drain region 130 (which may be referred to as a first source/drain region) selected from the plurality of source/drain regions 130 at a backside surface of the selected source/drain region 130 (or the first source/drain region). The backside source/drain contact BCA may pass through a lower portion of the source/drain region 130 corresponding thereto in a vertical direction (Z direction) from a backside of the source/drain region 130.

A backside metal silicide film 198 may be between the backside source/drain contact BCA and the source/drain region 130 connected to the backside source/drain contact BCA, from among the plurality of source/drain regions 130. The backside source/drain contact BCA may be connected to the source/drain region 130 corresponding thereto through the backside metal silicide film 198. A constituent material of the backside metal silicide film 198 may substantially be the same as that of the metal silicide film 172, which has been described above with reference to FIGS. 3, 5, and 6.

Although FIG. 8A illustrates a configuration in which a source/drain contact CA is connected to a frontside surface of the source/drain region 130 connected to the backside source/drain contact BCA, the inventive concept is not limited thereto. Unlike shown in FIG. 8A, the source/drain contact CA may not be connected to the source/drain region 130 that is connected to the backside source/drain contact BCA. As used herein, the backside surface and the frontside surface of the source/drain region 130 refer to surfaces of the source/drain region 130, which are opposite to each other in the vertical direction (Z direction). The backside surface of the source/drain region 130 may be a surface of the source/drain region 130, which faces the backside power rail MPR, and the frontside surface of the source/drain region 130 may be a surface of the source/drain region 130, which faces an etch stop insulating film 174.

The backside power rail MPR may be apart from the etch stop insulating film 174 in the vertical direction (Z direction) with the source/drain region 130 therebetween. As shown in FIG. 8A, the IC device 300 may include a plurality of backside bulk insulating films BBI, which are arranged in a line in a first lateral direction (X direction) and each extend lengthwise in a second lateral direction (Y direction). A plurality of backside power rails MPR may be separated from each other by the plurality of backside bulk insulating films BBI in a plurality of backside power rails MPR in the first lateral direction (X direction). Each of the plurality of backside power rails MPR may be between two adjacent ones of the plurality of backside bulk insulating films BBI in the first lateral direction (X direction). The backside source/drain contact BCA may be integrally connected to one backside power rail MPR selected from the plurality of backside power rails MPR. In the IC device 300, the plurality of nanosheet stacks NSS may be apart from the plurality of backside bulk insulating films BBI in the vertical direction (Z direction).

Each of the plurality of backside bulk insulating films BBI may be in contact with a pair of backside power rails MPR, which are selected from the plurality of backside power rails MPR and adjacent to each other. Each of the plurality of backside bulk insulating films BBI may extend lengthwise from a space between a pair of backside power rails MPR, which are adjacent to each other, toward a selected one of the plurality of gate lines 160 in the vertical direction (Z direction). In embodiments, each of the plurality of backside bulk insulating films BBI may include a nitrogen (N)-containing insulating film. For example, each of the plurality of backside bulk insulating films BBI may include silicon nitride (SiN), silicon carbonitride (SiCN), silicon oxycarbonitride (SiOCN), or a combination thereof, without being limited thereto.

The backside source/drain contact BCA may extend lengthwise in the vertical direction (Z direction) between a pair of backside bulk insulating films BBI, which are adjacent to each other, from among the plurality of backside bulk insulating films BBI. From among the plurality of backside power rails MPR, the backside power rail MPR integrally connected to the backside source/drain contact BCA may be apart from the source/drain region 130 with the backside source/drain contact BCA therebetween in the vertical direction (Z direction).

In embodiments, the backside source/drain contact BCA and the backside power rail MPR may be simultaneously formed using a single process, and the backside source/drain contact BCA and the backside power rail MPR may include the same material. In other embodiments, the backside source/drain contact BCA and the backside power rail MPR may be formed using separate processes, and an interface may be present between the backside source/drain contact BCA and the backside power rail MPR. In embodiments, the backside source/drain contact BCA and the backside power rail MPR may include a single metal. In other embodiments, the source/drain contact CA may include a metal plug and a conductive barrier film surrounding the metal plug. The metal plug may include molybdenum (Mo), tungsten (W), cobalt (Co), ruthenium (Ru), manganese (Mn), titanium (Ti), tantalum (Ta), aluminum (Al), copper (Cu), a combination thereof, or an alloy thereof, without being limited thereto. The conductive barrier film may include a metal or a conductive metal nitride. For example, the conductive barrier film may include Ti, Ta, W, TiN, TaN, WN, WCN, TiSiN, TaSiN, WSiN, or a combination thereof, without being limited thereto.

The plurality of backside bulk insulating films BBI may include a pair of backside bulk insulating films BBI, which are respectively on both sides of the backside source/drain contact BCA with the backside source/drain contact BCA therebetween in the first lateral direction (X direction). Each of the pair of backside bulk insulating films BBI may overlap one gate line 160 selected from the plurality of gate lines 160 in the vertical direction (Z direction) and extend lengthwise in the vertical direction (Z direction). The pair of backside bulk insulating films BBI may include portions facing the backside source/drain contact BCA in the first lateral direction (X direction). Each of the plurality of backside bulk insulating films BBI may contact a gate dielectric film 152.

As shown in FIG. 8A, the IC device 300 may include a plurality of semiconductor blocks SB. From among the plurality of semiconductor blocks SB, some semiconductor blocks SB may cover a sidewall of the backside source/drain contact BCA in the first lateral direction (X direction). From among the plurality of semiconductor blocks SB, some other semiconductor blocks SB may be in contact with a backside surface of the source/drain region 130 connected to the source/drain contact CA. Each of the plurality of semiconductor blocks SB may include silicon (Si).

From among the plurality of semiconductor blocks SB, at least some semiconductor blocks SB may cover a sidewall of the backside bulk insulating film BBI in the first lateral direction (X direction). The plurality of semiconductor blocks SB may be in contact with the gate dielectric film 152 covering a lowermost surface of the gate line 160. As used herein, the lowermost surface of the gate line 160 may refer to a surface of the gate line 160, which is closest to the backside power rail MPR.

As shown in FIG. 8B, both sidewalls of a portion of the backside bulk insulating film BBI, which are adjacent to the gate line 160 in the second lateral direction (Y direction), may be covered by a field insulating film 112. At least one of the plurality of semiconductor blocks SB may have a surface contacting the source/drain region 130.

As shown in FIG. 8B, the field insulating film 112 may have a surface facing the gate line 160 with the gate dielectric film 152 therebetween and a surface contacting the backside bulk insulating film BBI.

As shown in FIGS. 8A and 8B, the plurality of backside bulk insulating films BBI may overlap the plurality of nanosheet stacks NSS in the vertical direction (Z direction). Each of the plurality of nanosheet stacks NSS may be apart from the backside bulk insulating film BBI in the vertical direction (Z direction). The etch stop insulating film 174 may be apart from the gate line 160 the backside bulk insulating film BBI and the backside power rail MPR with the gate line 160 therebetween in the vertical direction (Z direction).

The IC device 300 described with reference to FIGS. 8A and 8B may have the same effects as those of the IC device 100, which have been described with reference to FIGS. 2 to 6.

Next, a method of manufacturing an IC device, according to embodiments, is described in detail.

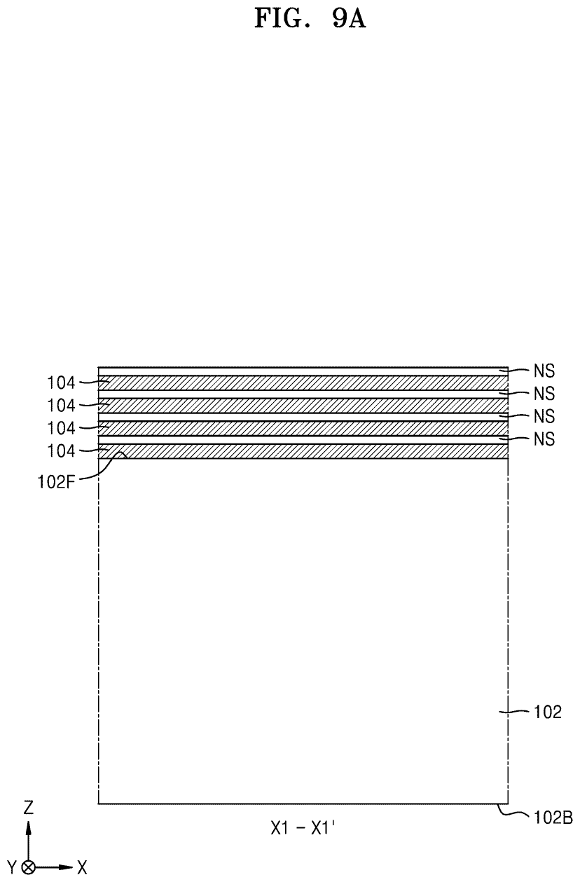

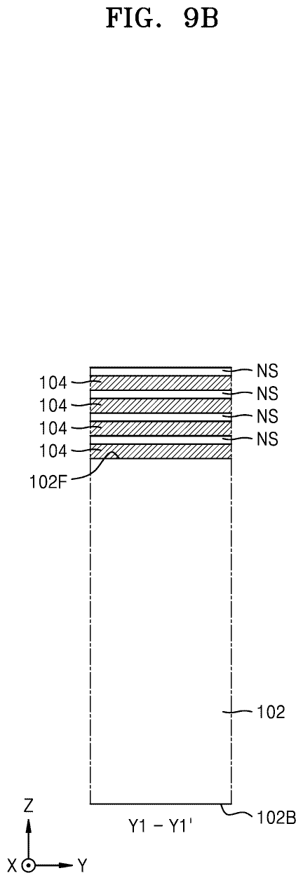

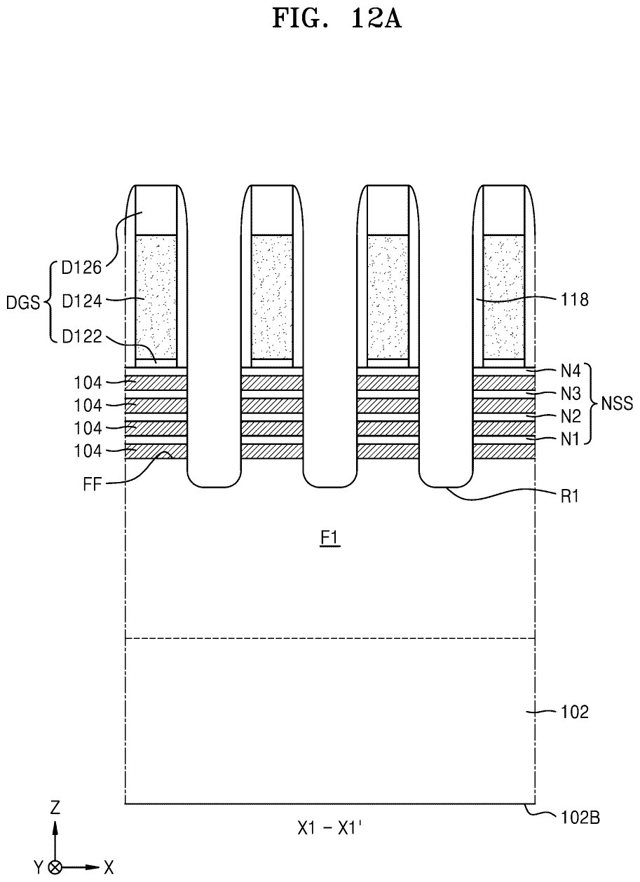

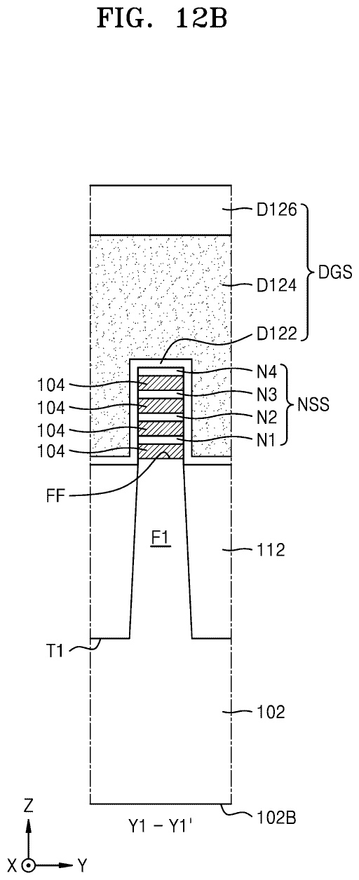

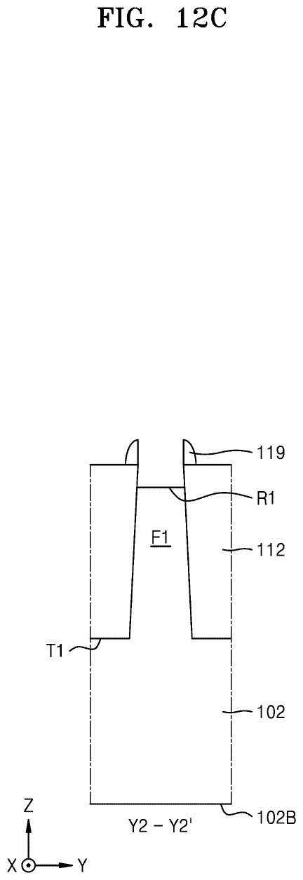

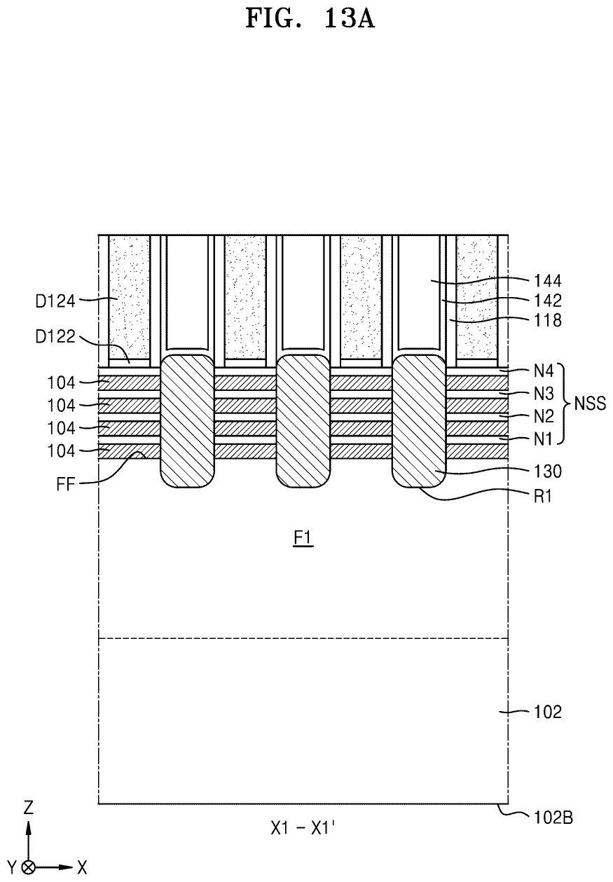

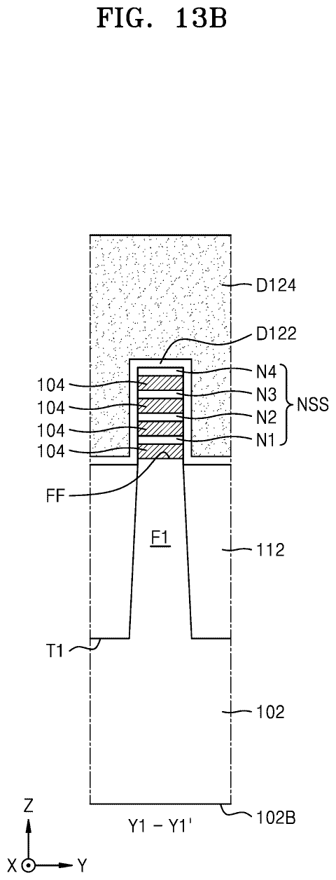

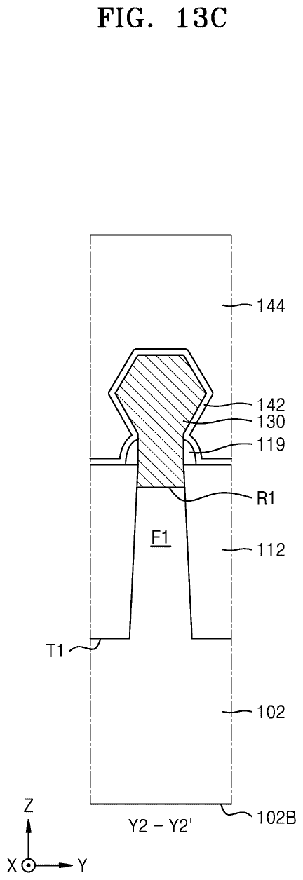

FIGS. 9A to 28 are cross-sectional views showing a process sequence of a method of manufacturing an IC device, according to embodiments. More specifically, FIGS. 9A, 10A, 11A, 12A, 13A, 14A, 15A, 16A, and 17 to 28 are cross-sectional views showing example cross-sectional structures of a portion corresponding to a cross-section taken along line X1-X1′ of FIG. 2, according to the process sequence. FIGS. 9B, 10B, 11B, 12B, 13B, 14B, 15B, and 16B are cross-sectional views showing example cross-sectional structures of a portion corresponding to a cross-section taken along line Y1-Y1′ of FIG. 2, according to the process sequence. FIGS. 12C and 13C are cross-sectional views showing example cross-sectional structures of a portion corresponding to a cross-section taken along line Y2-Y2′ of FIG. 2, according to the process sequence. An example of a method of manufacturing the IC device 100 described with reference to FIGS. 2 to 6 is described with reference to FIGS. 9A to 28. In FIGS. 9A to 28, the same reference numerals are used to denote the same elements as in FIGS. 2 to 6, and detailed descriptions thereof are omitted.

Referring to FIGS. 9A and 9B, a substrate 102 having a frontside surface 102F and a backside surface 102B, which are opposite to each other, may be prepared. A plurality of sacrificial semiconductor layers 104 and a plurality of nanosheet semiconductor layers NS may be alternately stacked one-by-one on the frontside surface 102F of the substrate 102 to form a stack structure.

In the stack structure, the plurality of sacrificial semiconductor layers 104 and the plurality of nanosheet semiconductor layers NS may include semiconductor materials having different etch selectivities from each other. In embodiments, the plurality of nanosheet semiconductor layers NS may include a Si layer, and the plurality of sacrificial semiconductor layers 104 may include a SiGe film. The SiGe film included in the sacrificial semiconductor layer 104 may have a constant Ge content, which is selected in a range of about 5 at % to about 50 at %, for example, about 10 at % to about 40 at %. In embodiments, the plurality of sacrificial semiconductor layers 104 may each include a SiGe film and have the same Ge content.

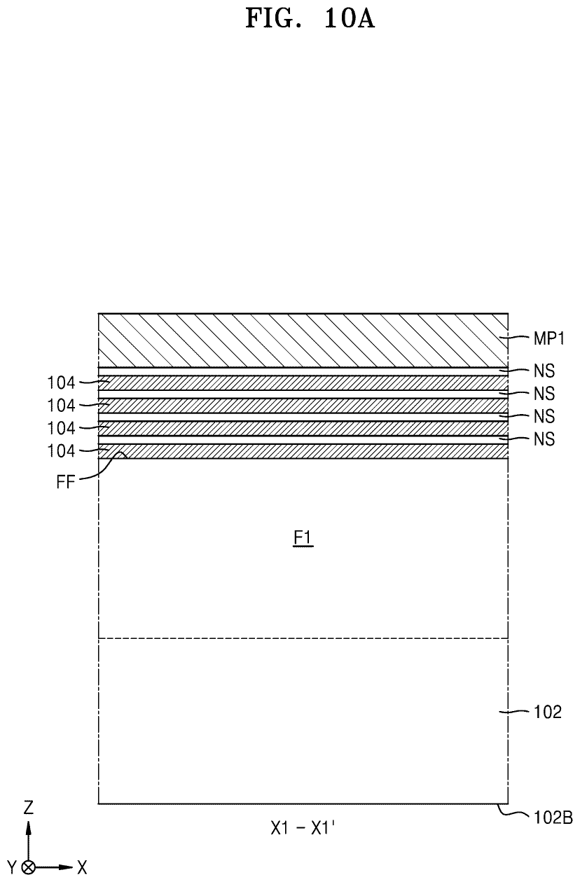

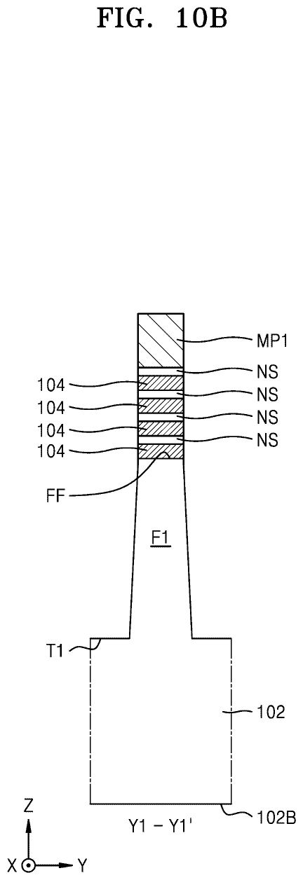

Referring to FIGS. 10A and 10B, a mask pattern MP1 having openings exposing a top surface of the stack structure may be formed on the resultant structure of FIGS. 9A and 9B. The mask pattern MP1 may have a stack structure of a silicon oxide film pattern and a silicon nitride film pattern. The mask pattern MP1 may include portions extending parallel to each other in a first lateral direction (X direction) on the substrate 102.

A portion of each of the plurality of sacrificial semiconductor layers 104, the plurality of nanosheet semiconductor layers NS, and the substrate 102 may be etched using the mask pattern MP1 as an etch mask, and thus, a plurality of fin-type active regions F1 may be formed on the substrate 102. A plurality of trenches T1 may be defined by the plurality of fin-type active regions F1 on the substrate 102. A portion of each of the plurality of sacrificial semiconductor layers 104 and the plurality of nanosheet semiconductor layers NS may remain on a fin top surface FF of each of the plurality of fin-type active regions F1.

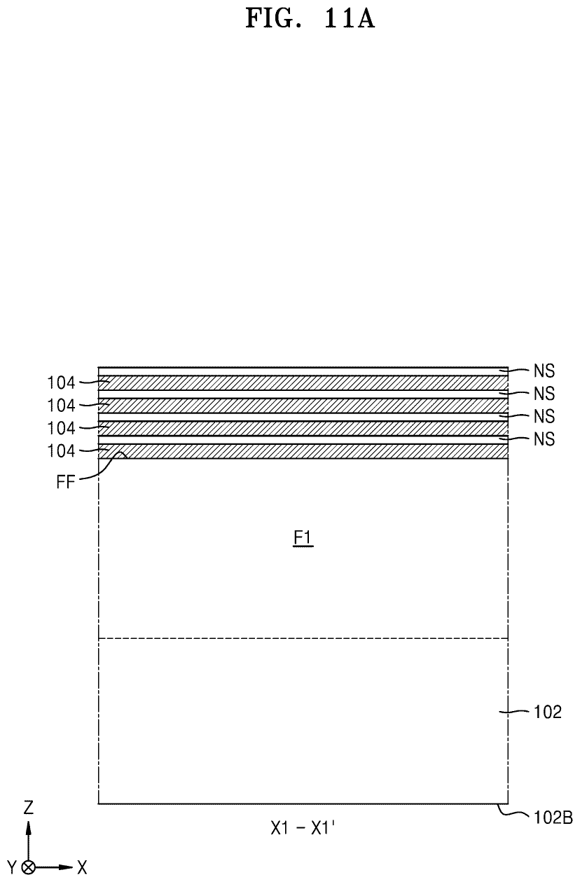

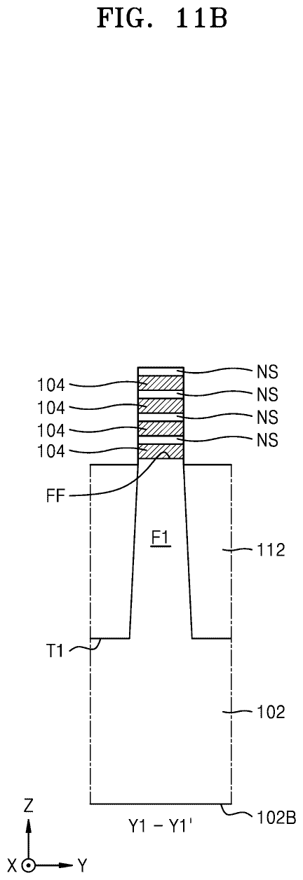

Referring to FIGS. 11A and 11B, a field insulating film 112 may be formed on the resultant structure of FIGS. 10A and 10B. The field insulating film 112 may be formed to fill the plurality of trenches T1 and sidewalls of each of the plurality of fin-type active regions F1.

The formation of the field insulating film 112 may include forming an insulating film having such a sufficient thickness as to fill the plurality of trenches T1 on the resultant structure of FIGS. 10A and 10B, planarizing the obtained resultant structure to expose a top surface of the mask pattern MP1, removing the exposed mask pattern MP1, and performing a recess process of removing a portion of the insulating film. Thus, the field insulating film 112 including the remaining portion of the insulating film may be formed. After the field insulating film 112 is formed, a stack structure including the plurality of sacrificial semiconductor layers 104 and the plurality of nanosheet semiconductor layers NS, which remain on the substrate 102, may protrude over a top surface of the field insulating film 112, and a top surface of an uppermost one of the plurality of nanosheet semiconductor layers NS may be exposed.

Referring to FIGS. 12A, 12B, and 12C, a plurality of dummy gate structures DGS may be formed on the resultant structure of FIGS. 11A and 11B. Each of the plurality of dummy gate structures DGS may be formed to extend lengthwise in a second lateral direction (Y direction). Each of the plurality of dummy gate structures DGS may include a dummy oxide film D122, a dummy gate layer D124, and a capping layer D126, which are sequentially stacked on the stack structure including the plurality of sacrificial semiconductor layers 104 and the plurality of nanosheet semiconductor layers NS. In embodiments, the dummy gate layer D124 may include polysilicon, and the capping layer D126 may include a silicon nitride film.

As shown in FIG. 12A, a plurality of insulating spacers 118 may be respectively formed on both sidewalls of the plurality of dummy gate structures DGS. A portion of each of the plurality of sacrificial semiconductor layers 104 and the plurality of nanosheet semiconductor layers NS and a portion of the fin-type active region F1 may be etched by using the plurality of dummy gate structures DGS and the plurality of insulating spacers 118 as etch masks. Thus, the plurality of nanosheet semiconductor layers NS may be divided into a plurality of nanosheet stacks NSS including the first to fourth nanosheets N1, N2, N3, and N4, and a plurality of recesses R1 may be formed in the fin-type active region F1. Widths of the first to fourth nanosheets N1, N2, N3, and N4 in the first lateral direction (X direction) may be defined by the plurality of recesses R1.

The plurality of recesses R1 may be formed by using a dry etching process, a wet etching process, or a combination thereof. During the formation of the plurality of insulating spacers 118 and the plurality of recesses R1, as shown in FIG. 12C, a plurality of side insulating spacers 119 may be formed adjacent to the plurality of recesses R1 on the field insulating film 112 on both sides of each of the fin-type active region F1 in the second lateral direction (Y direction).

Referring to FIGS. 13A, 13B, and 13C, in the resultant structure of FIGS. 12A, 12B, and 12C, a plurality of source/drain regions 130 may be formed to fill the plurality of recesses R1. To form the plurality of source/drain regions 130, a semiconductor material may be epitaxially grown from a sidewall of each of the first to fourth nanosheets N1, N2, N3, and N4 and a surface of the fin-type active region F1, which are exposed at the plurality of recesses R1.

In embodiments, to form the plurality of source/drain regions 130, a low-pressure chemical vapor deposition (LPCVD) process, a selective epitaxial growth (SEG) process, or a cyclic deposition and etching (CDE) process may be performed by using source materials including an element semiconductor precursor. The element semiconductor precursor may include an element, such as silicon (Si) and germanium (Ge).

In embodiments, the source/drain region 130 may include a SiGe layer doped with boron (B). In this case, to form the plurality of source/drain regions 130, boron (B) ions may be doped in-situ while supplying a Si source and a Ge source onto the substrate 102. Silane (SiH₄), disilane (Si₂H₆), trisilane (Si₃H₈), and/or dichlorosilane (SiH₂Cl₂) may be used as the Si source, without being limited thereto. Germane (GeH₄), digermane (Ge₂H₆), trigermane (Ge₃H₈), tetragermane (Ge₄H₁₀), and/or dichlorogermane (Ge₂H₂Cl₂) may be used as the Ge source, without being limited thereto. Diborane (B₂H₆), triborane, tetraborane, and/or pentaborane may be used as the B source, without being limited thereto.

In other embodiments, the plurality of source/drain regions 130 may include a Si layer doped with phosphorus (P). In this case, to form the plurality of source/drain regions 130, phosphorus (P) ions may be doped in-situ while supplying a Si source onto the substrate 102. The Si source may be selected from the materials described above. Phosphine (PH₃) gas may be used as the phosphorus (P) ion source, without being limited thereto.

Afterwards, an insulating liner 142 may be formed to cover the resultant structure in which a plurality of source/drain regions 130 are formed, and an inter-gate dielectric film 144 may be formed on the insulating liner 142. A portion of each of the insulating liner 142 and the inter-gate dielectric film 144 may be etched to expose top surfaces of a plurality of capping layers (refer to D126 in FIGS. 12A and 12B). Thereafter, the plurality of capping layers D126 may be removed to expose the dummy gate layer D124, and the insulating liner 142 and the inter-gate dielectric film 144 may be partially removed such that a top surface of the inter-gate dielectric film 144 becomes at substantially the same level as a top surface of the dummy gate layer D124.

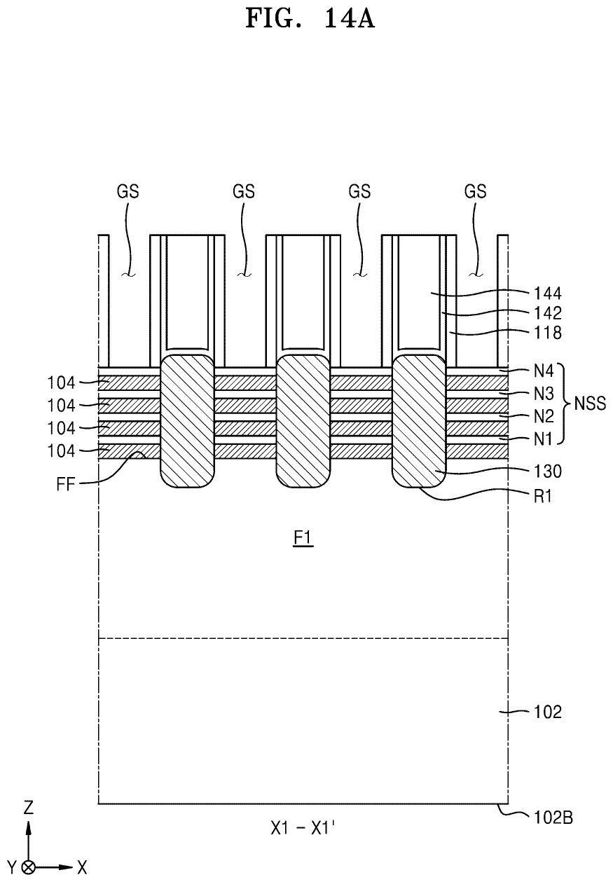

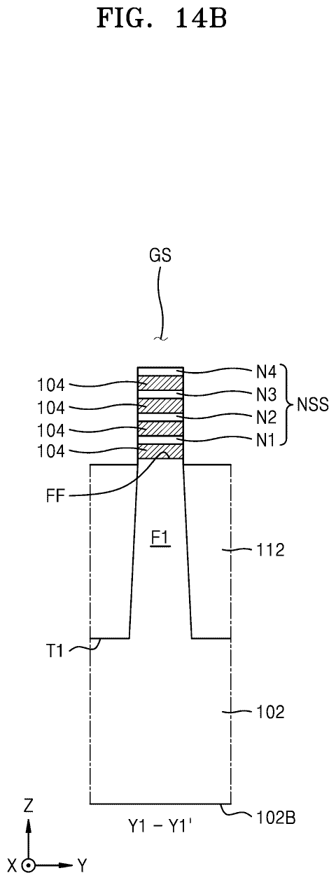

Referring to FIGS. 14A and 14B, the dummy gate layer D124 and the dummy oxide film D122 may be removed from the resultant structure of FIGS. 13A, 13B, and 13C to prepare a gate space GS.

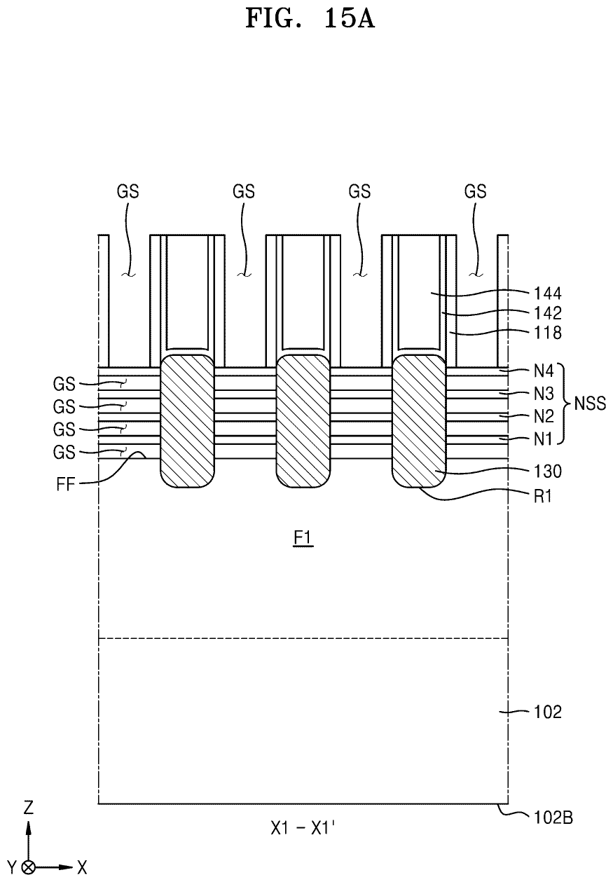

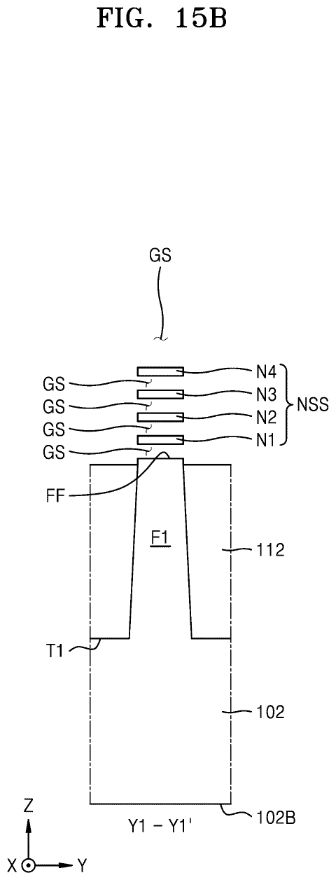

Referring to FIGS. 15A and 15B, in the resultant structure of FIGS. 14A and 14B, the plurality of sacrificial semiconductor layers 104 remaining on the substrate 102 may be selectively removed through the gate space GS. Thus, the gate space GS may extend to respective spaces between the first to fourth nanosheets N1, N2, N3, and N4 and a space between the first nanosheet N1 and the fin top surface FF of the fin-type active region F1.

In embodiments, to selectively remove the plurality of sacrificial semiconductor layers 104, etch selectivities of each of the first to fourth nanosheets N1, N2, N3, and N4 and fin-type active region F1 with respect to the plurality of sacrificial semiconductor layers 104 may be used. A liquid or gaseous etchant may be used to selectively remove the plurality of sacrificial semiconductor layers 104. In embodiments, to selectively remove the plurality of sacrificial semiconductor layers 104, a CH₃COOH-based etchant, for example, an etchant including a mixture of CH₃COOH, HNO₃, and HF or an etchant including a mixture of CH₃COOH, H₂O₂, and HF may be used, without being limited thereto.

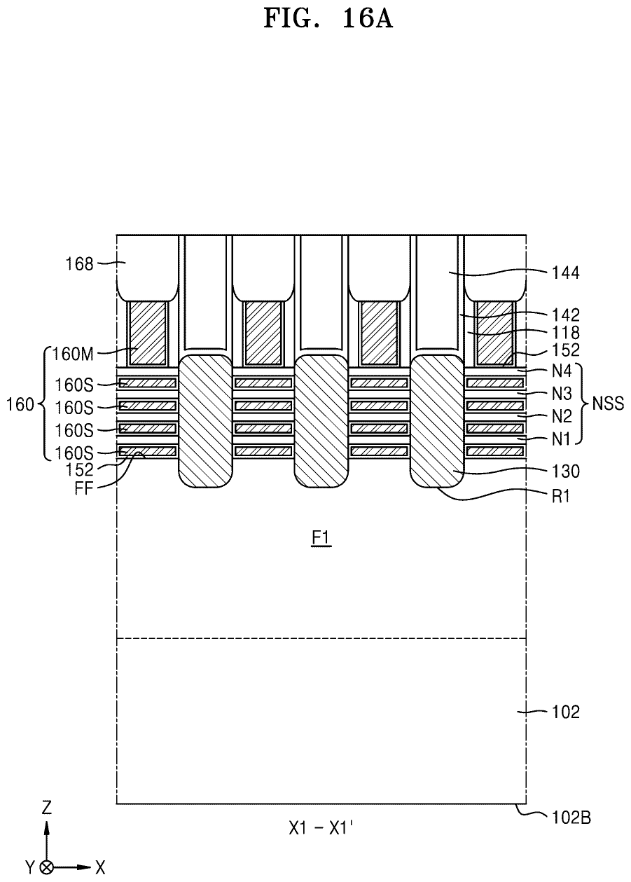

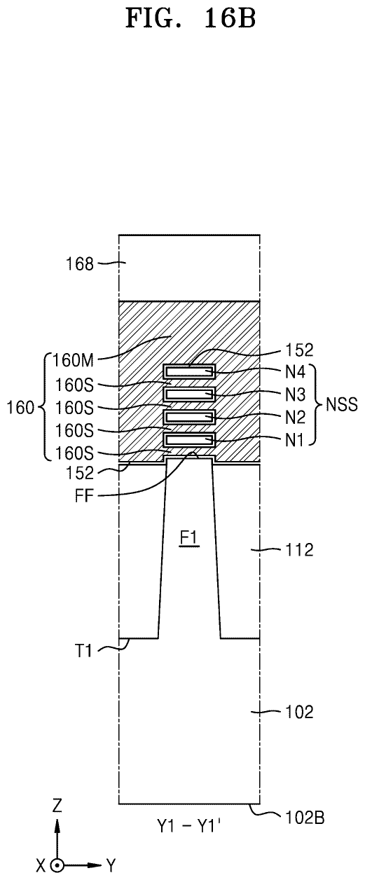

Referring to FIGS. 16A and 16B, in the resultant structure of FIGS. 15A and 15B, a gate dielectric film 152 may be formed to cover respective exposed surfaces of the first to fourth nanosheets N1, N2, N3, and N4 and the fin-type active region F1. The gate dielectric film 152 may be formed using an atomic layer deposition (ALD) process.

Afterwards, a gate line 160 filling the gate space (refer to GS in FIGS. 15A and 15B) may be formed on the gate dielectric film 152. Thereafter, a height of each of the gate line 160, the gate dielectric film 152, and the gate insulating spacer 118 may be reduced by removing a portion of each of the gate line 160, the gate dielectric film 152, and the gate insulating spacer 118 from a top surface of each thereof, and a plurality of capping insulating patterns 168 may be formed to cover the top surface of each of the gate line 160, the gate dielectric film 152, and the gate insulating spacer 118.

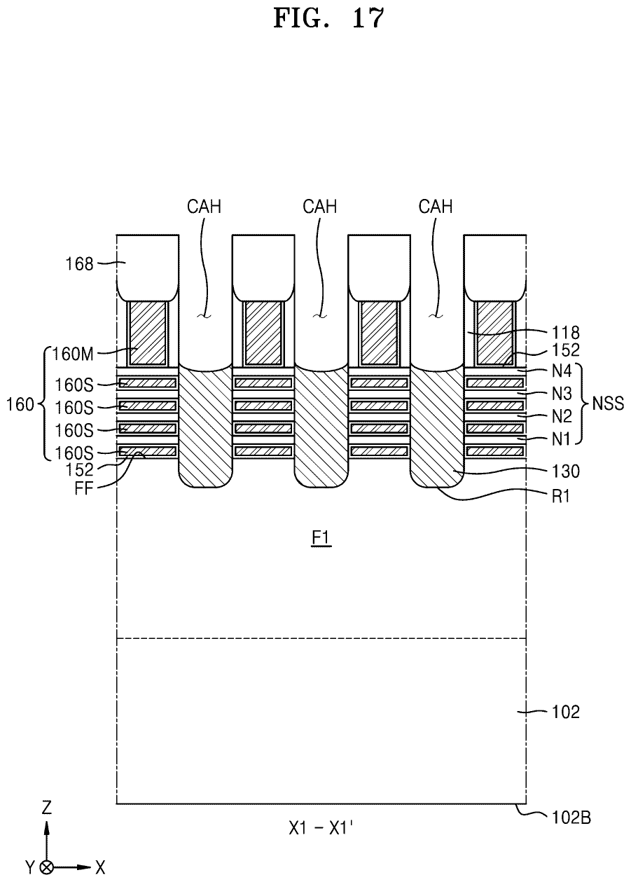

Referring to FIG. 17, in the resultant structure of FIGS. 16A and 16B, a portion of each of the insulating liner 142 and the inter-gate dielectric film 144 may be removed to form a plurality of source/drain contact holes CAH exposing the source/drain region 130. After the plurality of source/drain contact holes CAH are formed, a portion of a frontside surface of the source/drain region 130 exposed through the plurality of source/drain contact holes CAH may be removed.

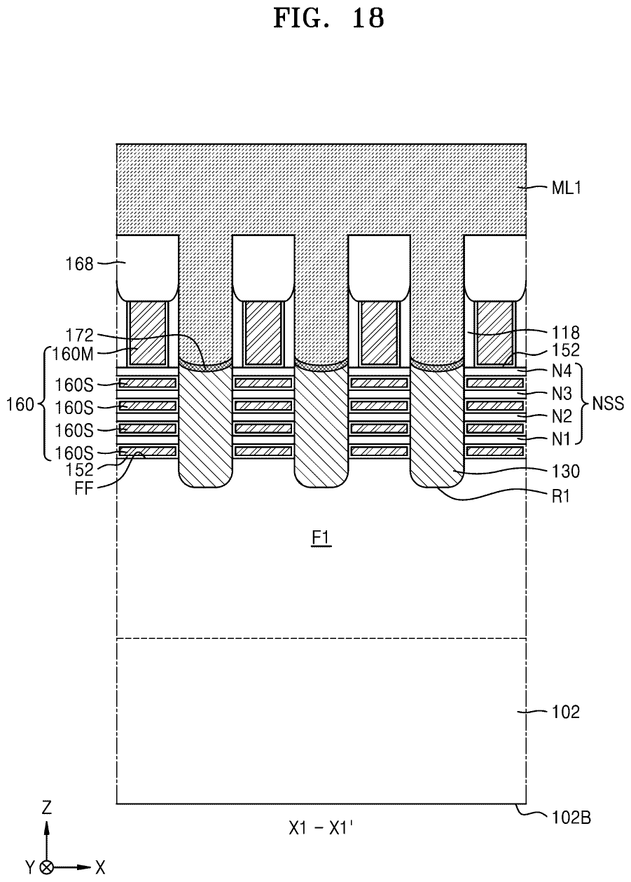

Referring to FIG. 18, in the resultant structure of FIG. 17, a metal silicide film 172 may be formed to cover the frontside surface of the source/drain region 130 exposed through the plurality of source/drain contact holes CAH, and a metal-containing layer ML1 filling the plurality of source/drain contact holes CAH may be formed on the metal silicide film 172. The metal-containing layer ML1 may include materials required to form a plurality of source/drain contacts (refer to CA in FIGS. 3, 5, and 6). For example, the formation of the metal-containing layer ML1 may include first forming a conductive barrier film and forming a metal plug on the conductive barrier film. Detailed configurations of the conductive barrier film and the metal plug are the same as those of the plurality of source/drain contacts CA, which have been described with reference to FIGS. 3, 5, and 6.

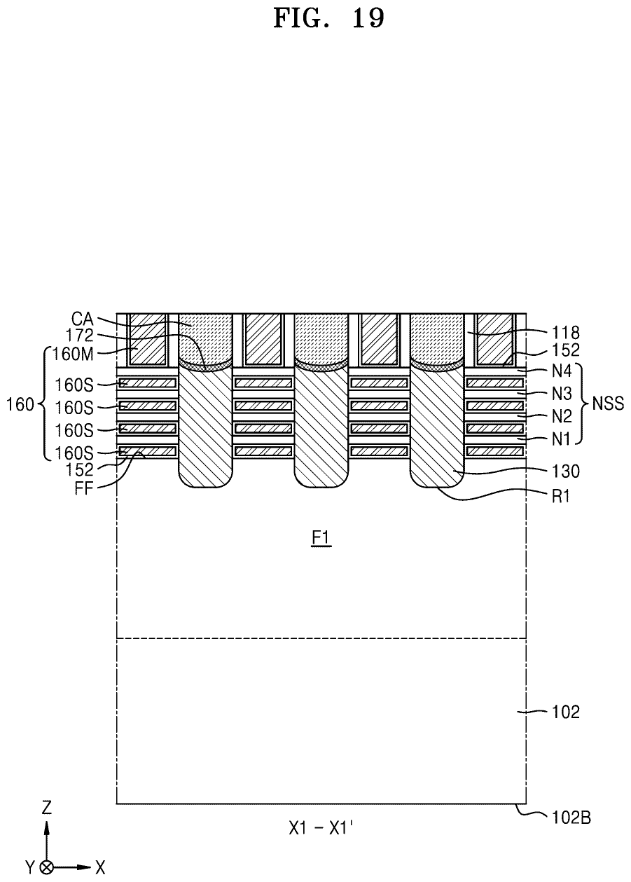

Referring to FIG. 19, in the resultant structure of FIG. 18, a portion of the metal-containing layer ML1 and the plurality of capping insulating patterns 168 may be removed, and thus, the plurality of source/drain contacts CA may be formed from the metal-containing layer ML1. The obtained resultant structure may be planarized to reduce a height of each of the plurality of gate lines 160 and the plurality of source/drain contacts CA in a vertical direction (Z direction). During the planarization of the obtained resultant structure as described above, a height of each of a plurality of gate dielectric films 152 and the plurality of gate insulating spacers 118 in the vertical direction (Z direction) may also be reduced.

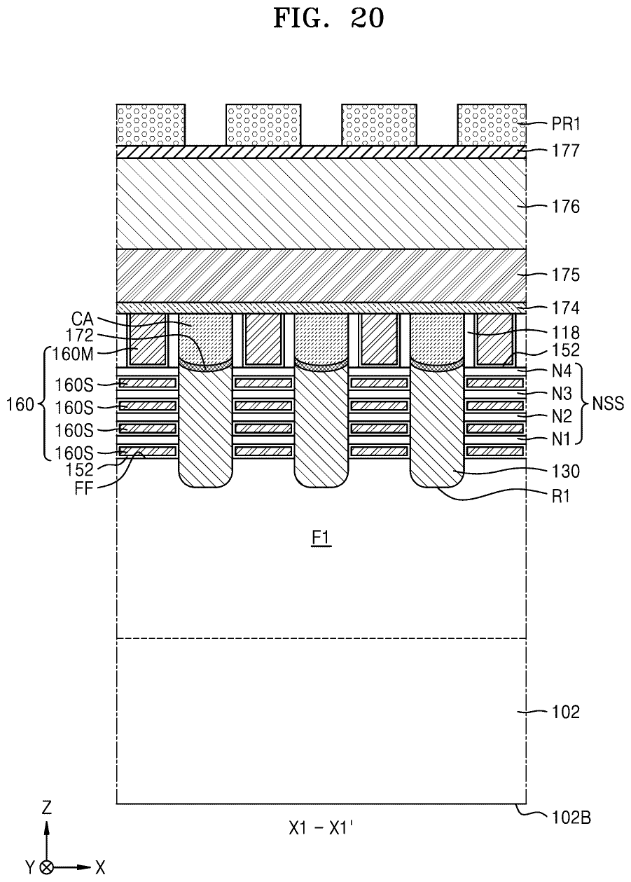

Referring to FIG. 20, an etch stop insulating film 174, a capping insulating film 175, a first hardmask film 176, a second hardmask film 177, and a first photoresist pattern PR1 may be sequentially formed on a planarized top surface of the resultant structure of FIG. 19. In embodiments, the first hardmask film 176 may include a carbon-containing film, such as a spin-on-hardmask (SOH) film, and the second hardmask film 177 may include a silicon oxynitride (SiON) film, without being limited thereto.

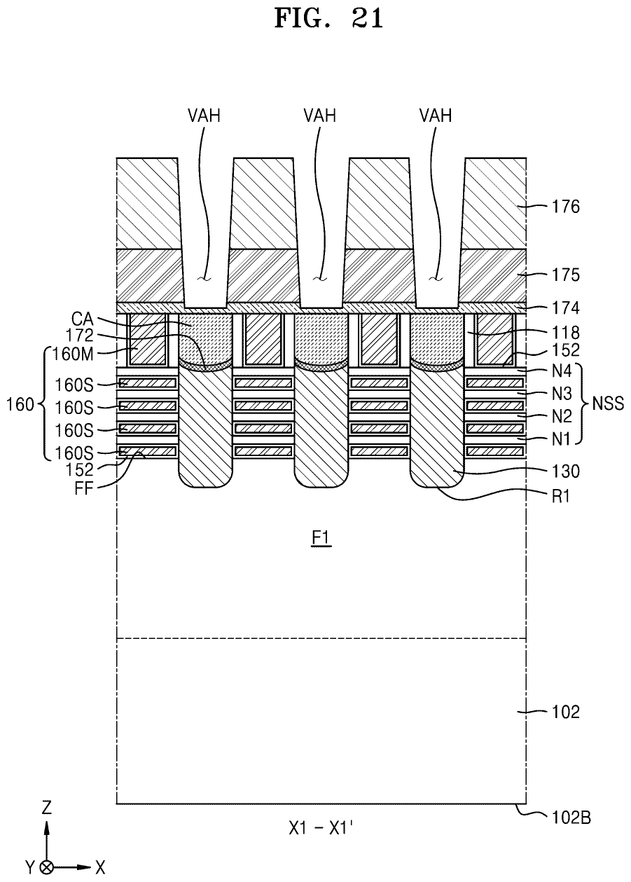

Referring to FIG. 21, in the resultant structure of FIG. 20, the second hardmask film 177 and the first hardmask film 176 may be sequentially etched by using the first photoresist pattern PR1 as an etch mask. The capping insulating film 175 may be etched using the obtained etching resultant structure as an etch mask and using the etch stop insulating film 174 as an etch stop layer to form a plurality of via contact holes VAH. During or after the formation of the plurality of via contact holes VAH, the first photoresist pattern PR1 and the second hardmask film 177 that remain in the resultant structure may be removed.

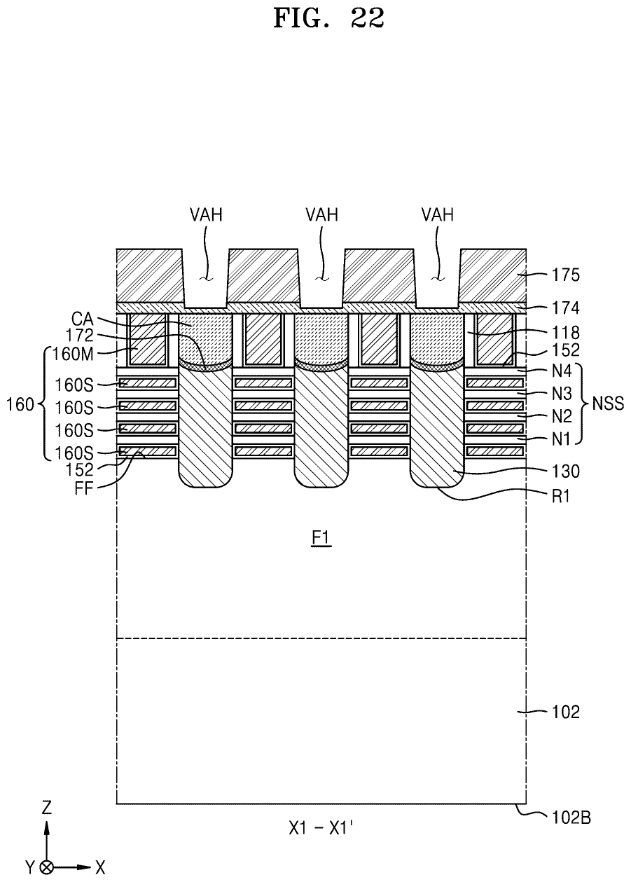

Referring to FIG. 22, the first hardmask film 176 that remains in the resultant structure of FIG. 21 may be removed to expose a top surface of the capping insulating film 175. When the first hardmask film 176 includes an SOH film, the remaining first hardmask film 176 may be removed using ashing and strip processes.

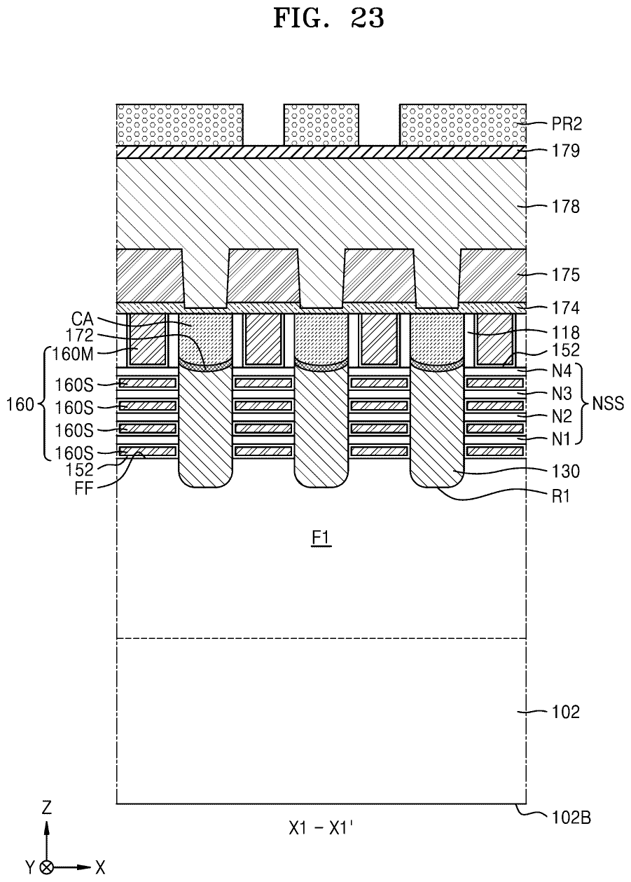

Referring to FIG. 23, in the resultant structure of FIG. 22, a third hardmask film 178 may be formed to fill the plurality of via contact holes VAH and cover the top surface of the capping insulating film 175, and a fourth hardmask film 179 and a second photoresist pattern PR2 may be sequentially formed on the third hardmask film 178. In embodiments, the third hardmask film 178 may include a carbon-containing film, such as an SOH film, and the fourth hardmask film 179 may include a SiON film, without being limited thereto.

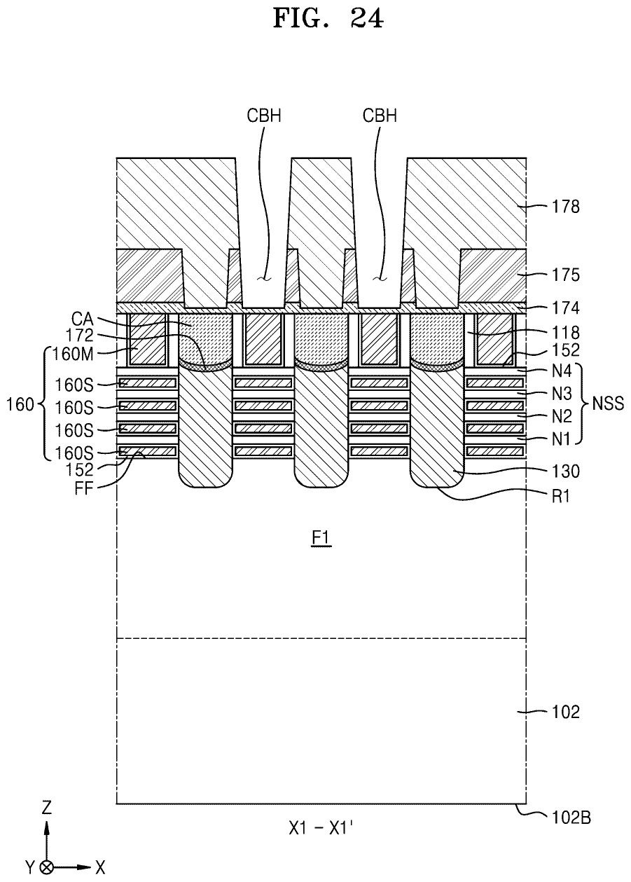

Referring to FIG. 24, in the resultant structure of FIG. 23, the fourth hardmask film 179 and the third hardmask film 178 may be sequentially etched by using the second photoresist pattern PR2 as an etch mask. The capping insulating film 175 may be etched using the obtained etching resultant structure as an etch mask and using the etch stop insulating film 174 as an etch stop layer to form a plurality of gate contact holes CBH. During or after the formation of the plurality of gate contact holes CBH, the second photoresist pattern PR2 and the fourth hardmask film 179 that remain in the resultant structure may be removed.

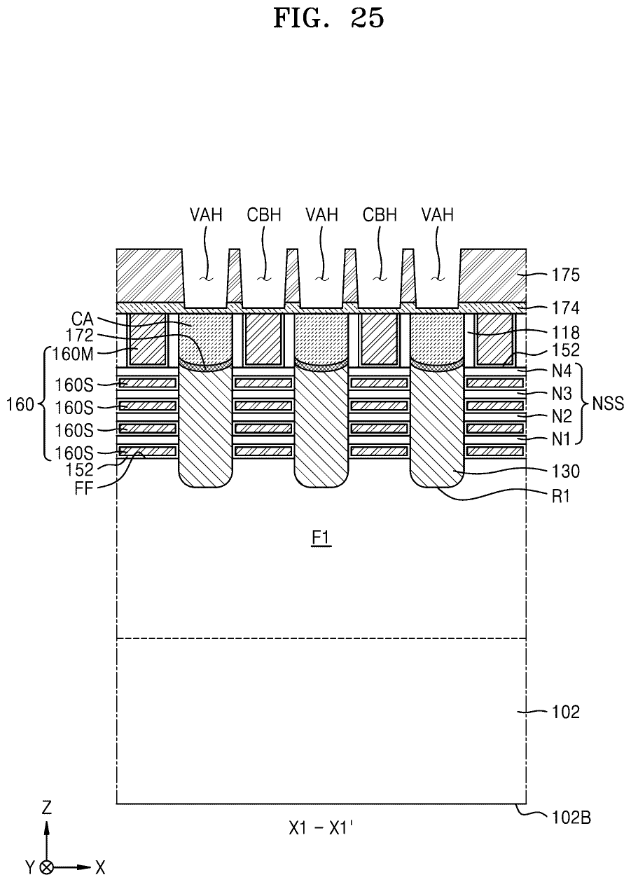

Referring to FIG. 25, the third hardmask film 178 that remains in the resultant structure of FIG. 24 may be removed to expose the top surface of the capping insulating film 175. When the third hardmask film 178 includes an SOH film, the remaining third hardmask film 178 may be removed using ashing and strip processes.

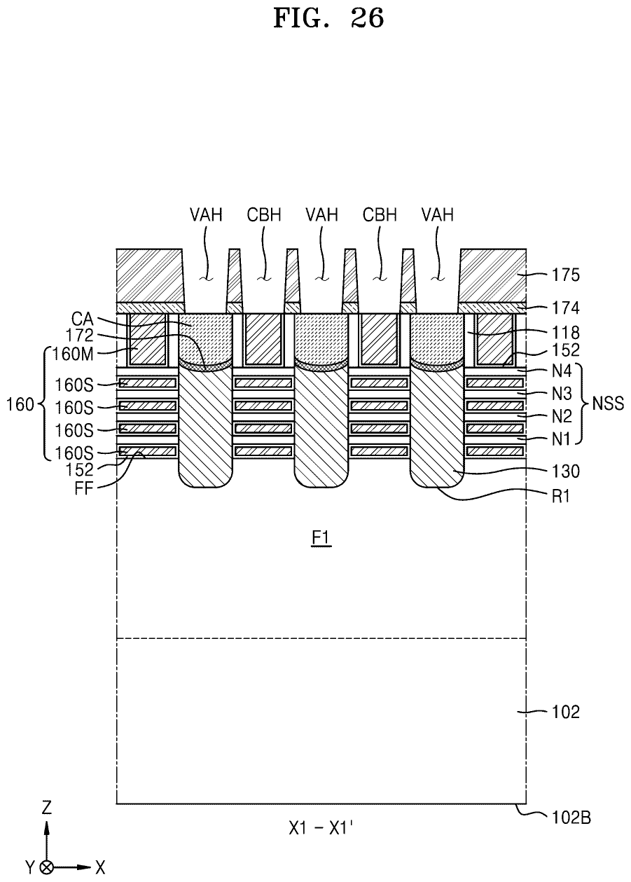

Referring to FIG. 26, portions of the etch stop insulating film 174, which are exposed through the plurality of via contact holes VAH and the plurality of gate contact holes CBH, may be removed. Thus, top surfaces of the source/drain contacts CA may be respectively exposed through the plurality of via contact holes VAH, and the top surfaces of the gate lines 160 may be respectively exposed through the plurality of gate contact holes CBH.

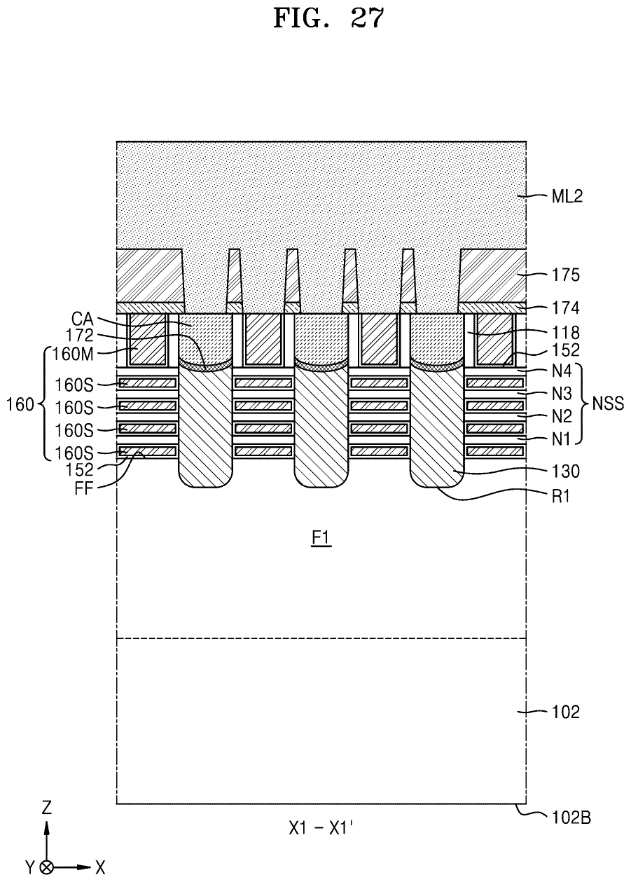

Referring to FIG. 27, in the resultant structure of FIG. 26, a metal-containing layer ML2 may be formed to fill the plurality of via contact holes VAH and the plurality of gate contact holes CBH and contact the top surface of each of the plurality of source/drain contacts CA and the top surface of each of the plurality of gate lines 160. The metal-containing layer ML2 may include materials required to form a plurality of gate contacts (refer to CB in FIGS. 3 to 6) and a plurality of via contacts (refer to VA in FIGS. 3 to 6). For example, the formation of the metal-containing layer ML2 may include first forming a conductive barrier film and forming a metal plug on the conductive barrier film. Detailed configurations of the conductive barrier film and the metal plug are the same as those of the plurality of gate contacts CB and the plurality of via contacts VA, which have been described with reference to FIGS. 3 to 6.

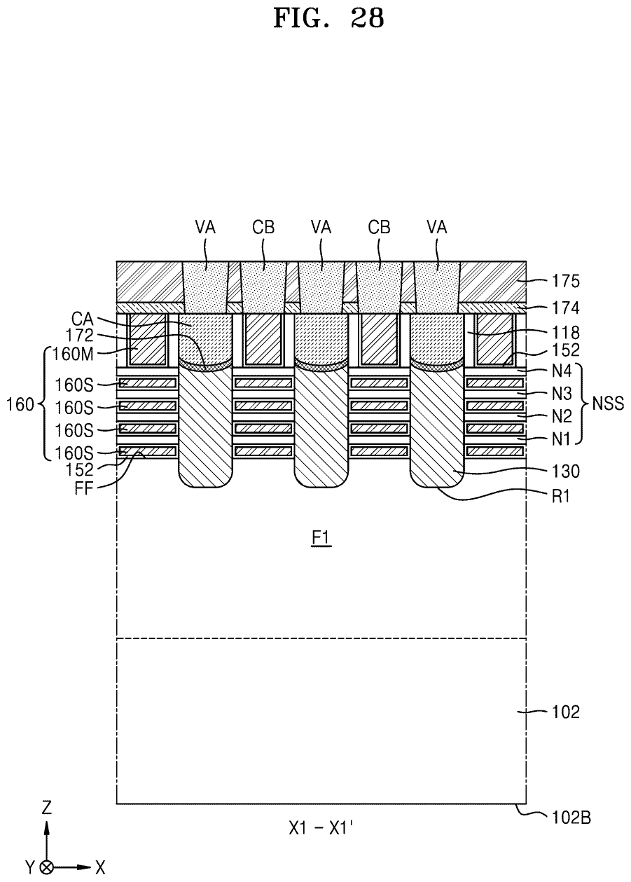

Referring to FIG. 28, in the resultant structure of FIG. 27, a portion of the metal-containing layer ML2 may be removed to expose the top surface of the capping insulating film 175, and the plurality of gate contacts CB and the plurality of via contacts VA, which include the remaining portions of the metal-containing layer ML2, may be formed.

Thereafter, as illustrated in FIGS. 3 to 6, an etch stop film 182 and an upper insulating film 184 may be sequentially formed on the resultant structure of FIG. 28 to form an upper insulating structure 180, and a plurality of upper wiring layers M1 may be formed to pass through the upper insulating structure 180 in the vertical direction (Z direction). Afterwards, when necessary, a BEOL structure including a plurality of wirings may be formed on the upper insulating structure 180 and the plurality of upper wiring layers M1.

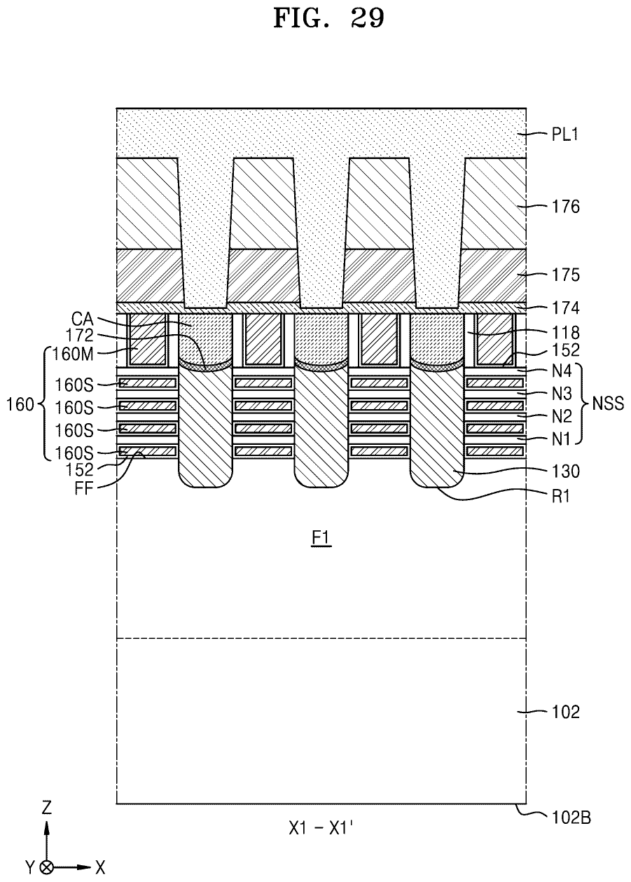

FIGS. 29 to 35 are cross-sectional views showing a process sequence of a method of manufacturing an IC device, according to embodiments. FIGS. 29 to 35 each illustrate a cross-sectional structure of a portion corresponding to a cross-section taken along line X1-X1′ of FIG. 2, according to the process sequence. Another example of a method of manufacturing the IC device 100 shown in FIGS. 2 to 6 is described with reference to FIGS. 29 to 35. In FIGS. 29 to 35, the same reference numerals are used to denote the same elements as in FIGS. 2 to 28, and detailed descriptions thereof are omitted.

Referring to FIG. 29, the processes described with reference to FIGS. 9A to 21 may be performed. Afterwards, a first pillar layer PL1 having such a sufficient thickness as to fill a plurality of via contact holes VAH may be formed on the resultant structure of FIG. 21. In embodiments, the first pillar layer PL1 may include a silicon oxide film, without being limited thereto. The first pillar layer PL1 may be formed using an ALD process.

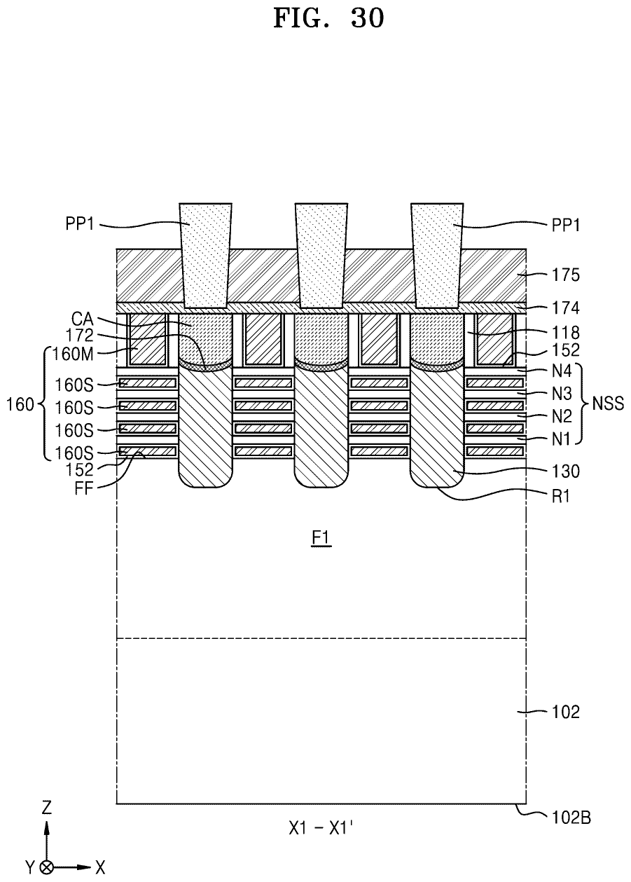

Referring to FIG. 30, in the resultant structure of FIG. 29, a portion of the first pillar layer PL1 may be etched back from a top surface of the first pillar layer PL1, and thus, a plurality of first pillars PP1 may be formed from the first pillar layer PL1 and a first hardmask film (refer to 176 in FIG. 29) may be exposed. Thereafter, the remaining first hardmask film 176 may be removed to expose a top surface of the capping insulating film 175 around each of the plurality of first pillars PP1. When the first hardmask film 176 includes an SOH film, the first hardmask film 176 may be removed using ashing and strip processes.

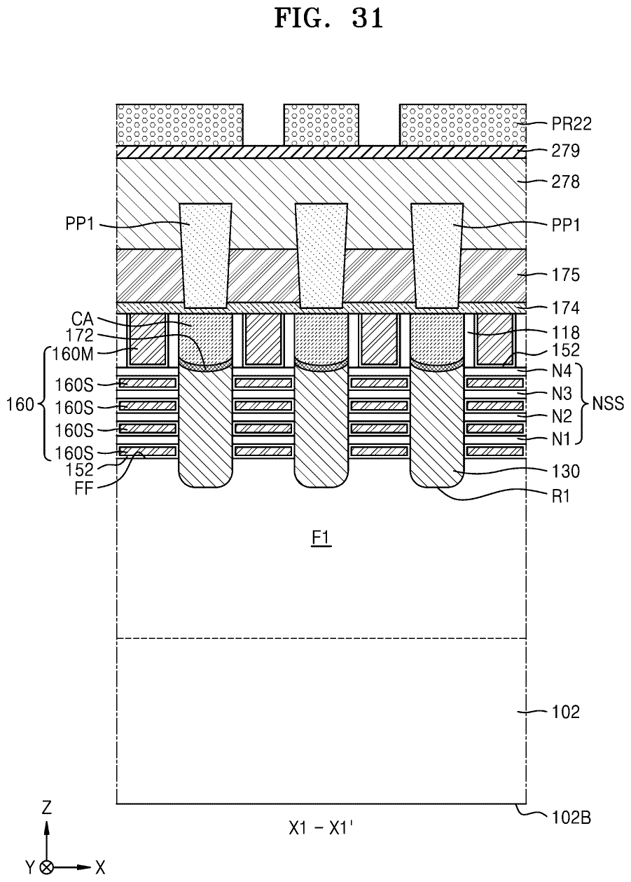

Referring to FIG. 31, in the resultant structure of FIG. 30, a third hardmask film 278 may be formed to fill respective spaces between the plurality of first pillars PP1 and cover a top surface of each of the plurality of first pillars PP1, and a fourth hardmask film 279 and a second photoresist pattern PR22 may be sequentially formed on the third hardmask film 178. In embodiments, the third hardmask film 278 may include a carbon-containing film, such as an SOH film, and the fourth hardmask film 279 may include a SiON film, without being limited thereto.

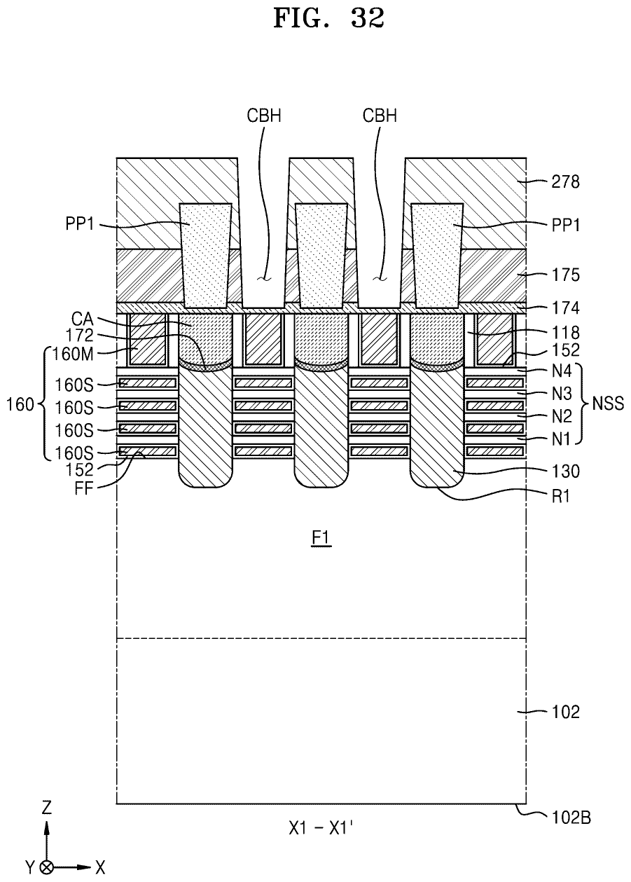

Referring to FIG. 32, in the resultant structure of FIG. 31, the fourth hardmask film 279 and the third hardmask film 278 may be sequentially etched by using the second photoresist pattern PR22 as an etch mask. The capping insulating film 175 may be etched using the obtained etching resultant structure as an etch mask and using the etch stop insulating film 174 as an etch stop layer to form a plurality of gate contact holes CBH. During or after the formation of the plurality of gate contact holes CBH, the second photoresist pattern PR22 and the fourth hardmask film 279 that remain in the resultant structure may be removed.

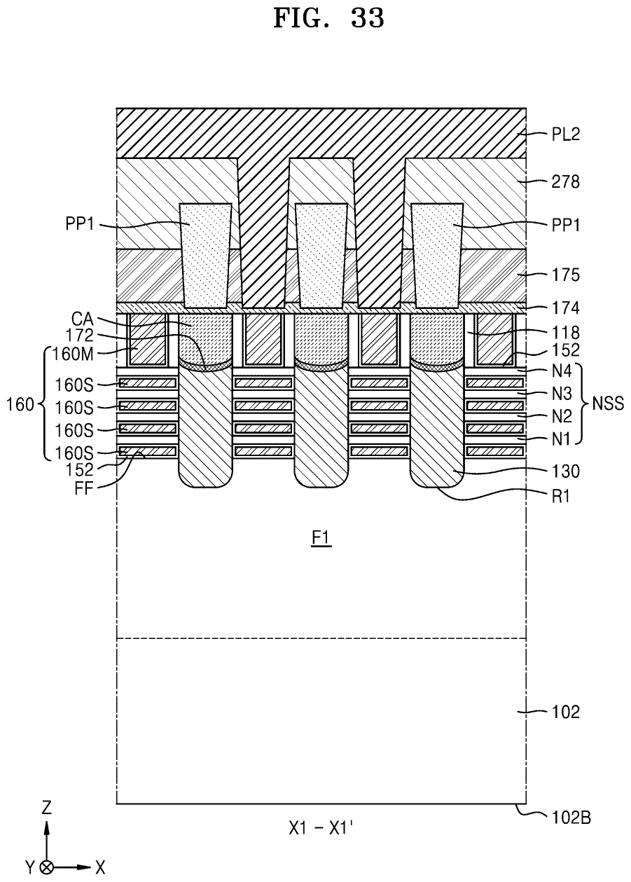

Referring to FIG. 33, a second pillar layer PL2 having such a sufficient thickness as to fill the plurality of contact holes CBH may be formed on the resultant structure of FIG. 32. In embodiments, the second pillar layer PL2 may include a silicon oxide film, without being limited thereto. The second pillar layer PL2 may be formed using an ALD process.

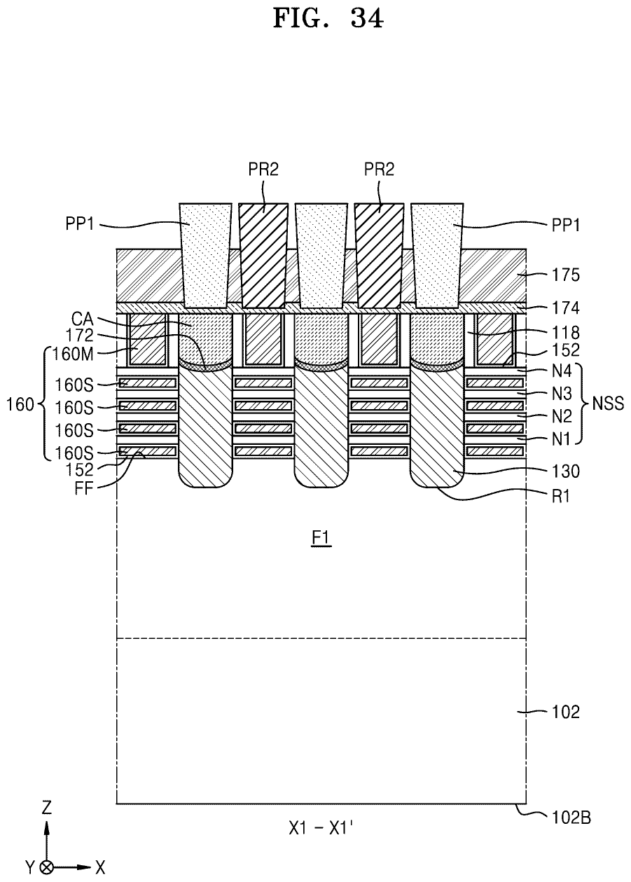

Referring to FIG. 34, in the resultant structure of FIG. 33, a portion of the second pillar layer PL2 may be etched back from a top surface of the second pillar layer PL2, and thus, a plurality of second pillars PR2 may be formed from the second pillar layer PL2 and the third hardmask film (refer to 278 in FIG. 33) may be exposed. Thereafter, the remaining third hardmask film 278 may be removed to expose the top surface of the capping insulating film 175 around each of the plurality of first pillars PP1 and the plurality of second pillars PR2. When the third hardmask film 278 includes an SOH film, the third hardmask film 278 may be removed using ashing and strip processes.

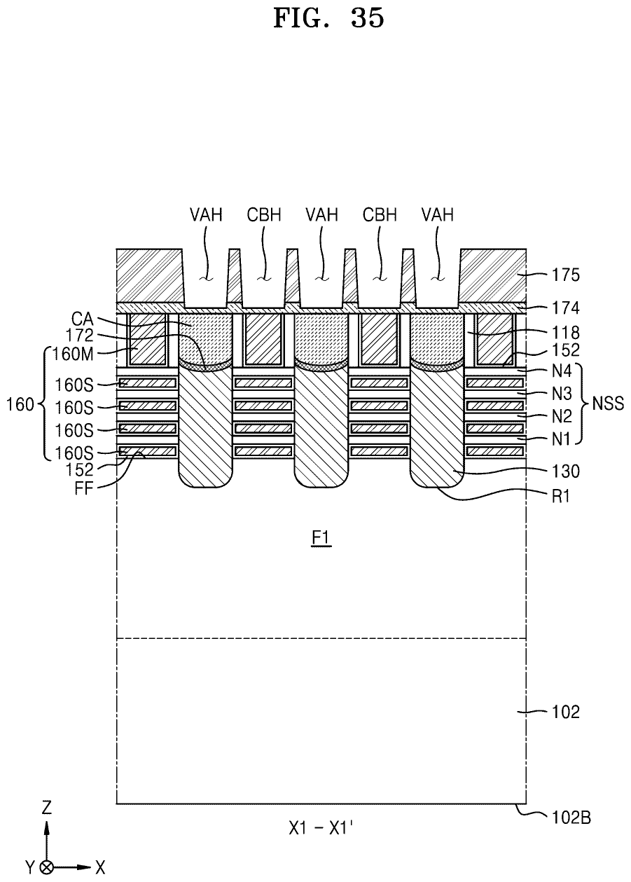

Referring to FIG. 35, in the resultant structure of FIG. 34, the plurality of first pillars PP1 and the plurality of second pillars PR2 may be removed such that the inside of each of the plurality of gate contact holes CBH and the plurality of via contact holes VAH is emptied and the etch stop insulating film 174 is exposed at the bottom of each of the plurality of gate contact holes CBH and the plurality of via contact holes VAH.

Afterwards, the processes described with reference to FIGS. 26 to 28 may be performed, and thus, the IC device 100 shown in FIGS. 2 to 6 may be manufactured.

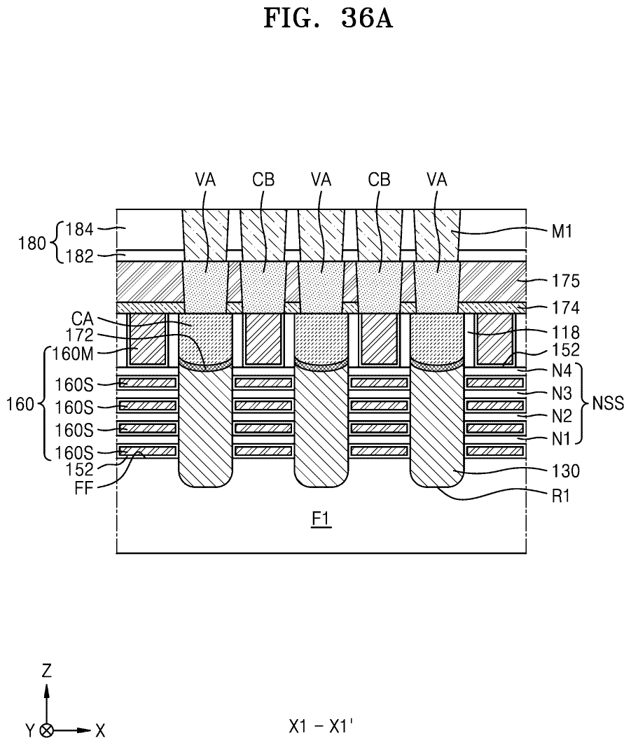

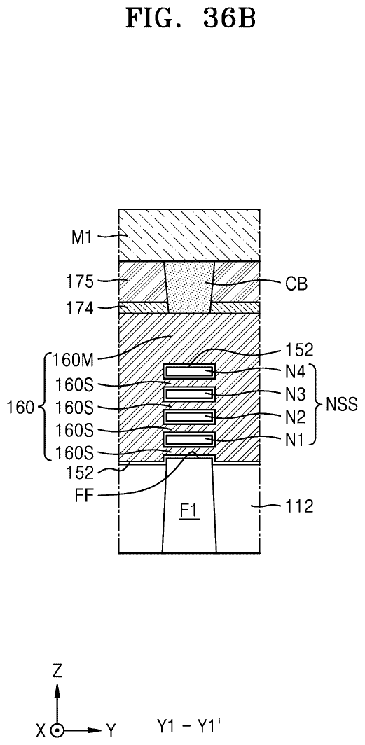

FIGS. 36A to 42 are cross-sectional views showing a process sequence of a method of manufacturing an IC device, according to embodiments. More specifically, FIGS. 36A, 37A, 38A, and 39 to 42 are cross-sectional views showing example cross-sectional structures of a portion corresponding to a cross-section taken along line X1-X1′ of FIG. 2, according to the process sequence. FIGS. 36B, 37B, and 38B are cross-sectional views showing example cross-sectional structures of a portion corresponding to a cross-section taken along line Y1-Y1′ of FIG. 2, according to the process sequence. An example of a method of manufacturing the IC device 300 described with reference to FIGS. 8A and 8B is described with reference to FIGS. 36A to 42. In FIGS. 36A to 42, the same reference numerals are used to denote the same elements as in FIGS. 2 to 35, and detailed descriptions thereof are omitted.

Referring to FIGS. 36A and 36B, in the resultant structure described with reference to FIGS. 3 to 6, the substrate 102 may be removed from the backside surface 102B of the substrate 102 to expose the plurality of fin-type active regions F1 and the field insulating film 112. A portion of each of the plurality of fin-type active regions F1 and the field insulating film 112 that are exposed may be further removed to reduce a thickness of each of the plurality of fin-type active regions F1 and the field insulating film 112 in a vertical direction (Z direction).

In embodiments, the process of removing the substrate 102 and the process of removing the portion of each of the plurality of fin-type active regions F1 and the field insulating film 112 may be performed using at least one process selected from a mechanical grinding process, a chemical mechanical polishing (CMP) process, a wet etching process, and a combination thereof.

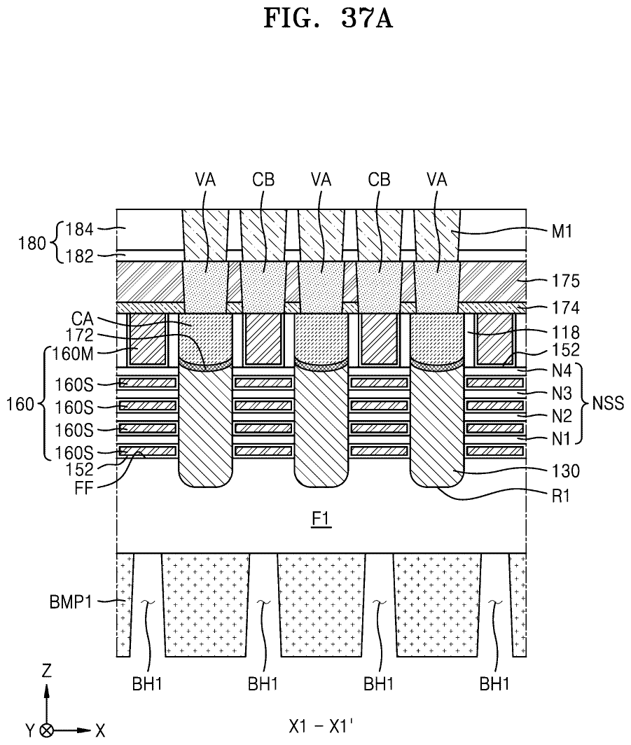

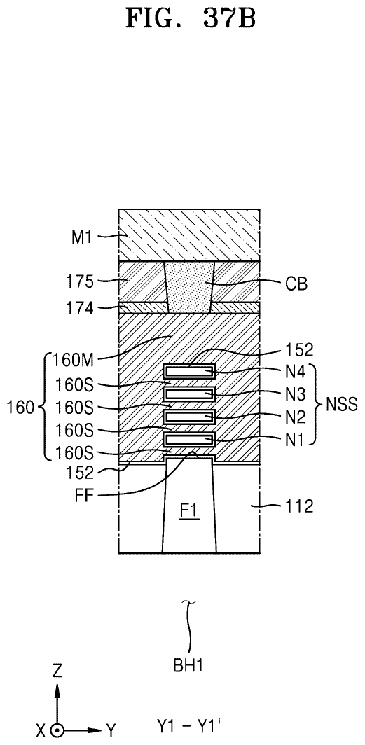

Referring to FIGS. 37A and 37B, in the resultant structure of FIGS. 36A and 36B, a first backside mask pattern BMP1 may be formed on the backside surface at which the plurality of fin-type active regions F1 and the field insulating film 112 are exposed. The first backside mask pattern BMP1 may have a plurality of line-shaped openings BH1, which extend lengthwise in a second lateral direction (Y direction). A portion of each of the plurality of fin-type active regions F1 and the field insulating film 112 may be exposed through the plurality of line-shaped openings BH1 of the first backside mask pattern BMP1. In embodiments, the first backside mask pattern BMP1 may include an SOH material, without being limited thereto.

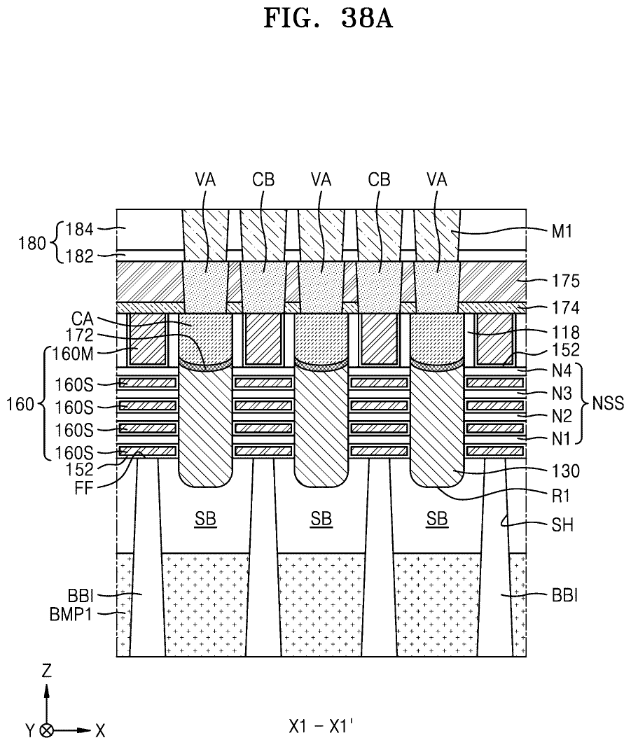

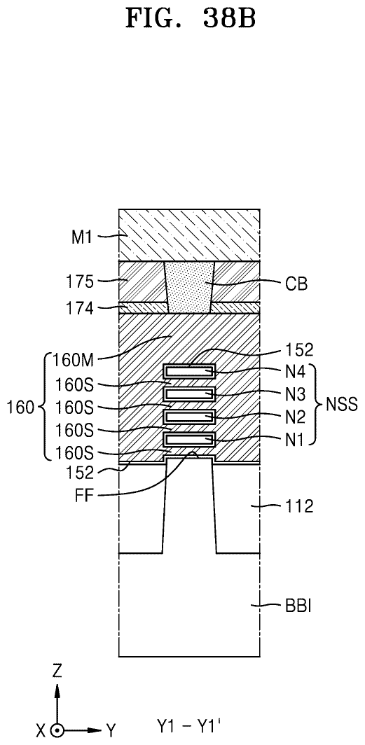

Referring to FIGS. 38A and 38B, in the resultant structure of FIGS. 37A and 37B, the plurality of fin-type active regions F1 may be selectively etched using the first backside mask pattern BMP1 as an etch mask, and thus, a plurality of vertical holes SH may be formed to expose the gate dielectric film 152. When the plurality of vertical holes SH are formed, each of the plurality of fin-type active regions F1 may be divided into a plurality of semiconductor blocks SB.

Thereafter, a plurality of backside bulk insulating films BB1 may be formed to fill the plurality of vertical holes SH and the plurality of line-shaped openings BH1. In embodiments, the plurality of backside bulk insulating films BBI may be formed using an ALD process or a chemical vapor deposition (CVD) process, without being limited thereto.

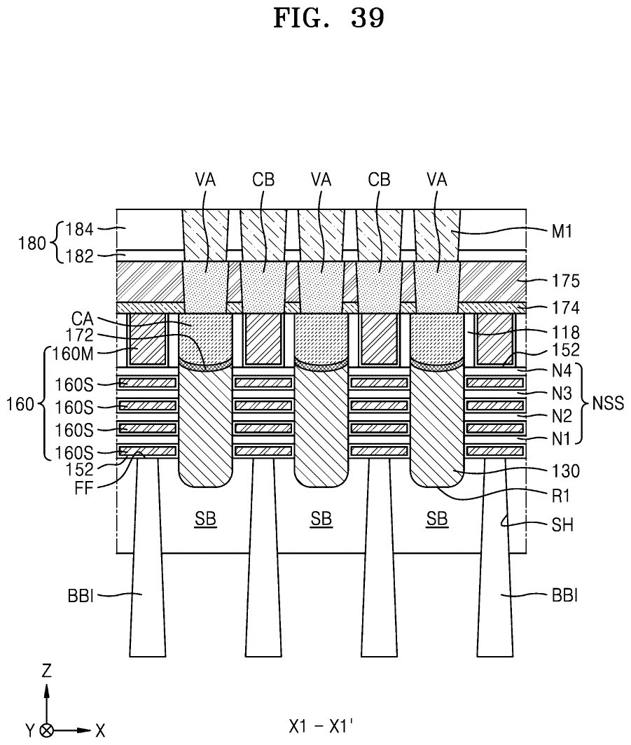

Referring to FIG. 39, the first backside mask pattern BMP1 may be removed from the resultant structure of FIGS. 38A and 38B. When the first backside mask pattern BMP1 includes an SOH material, the first backside mask pattern BMP1 may be removed using ashing and strip processes.

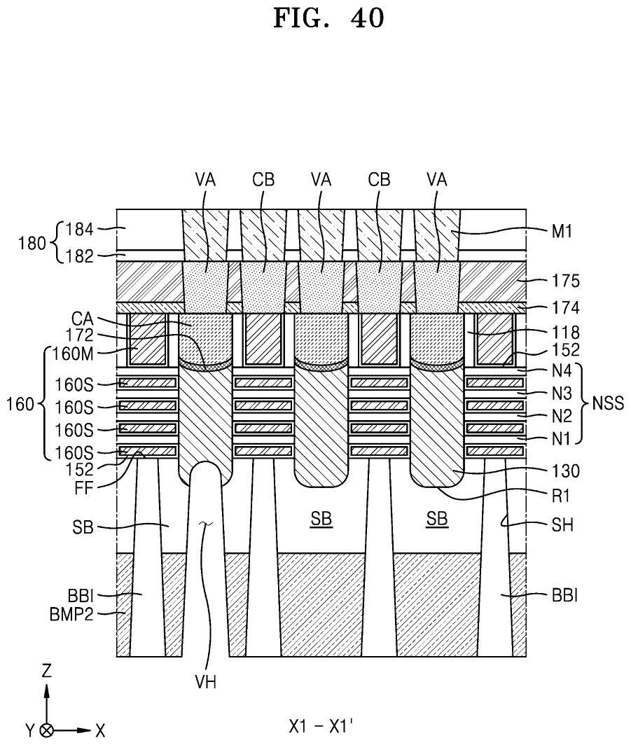

Referring to FIG. 40, the resultant structure of the process described with reference to FIG. 39 may be coated with an SOH material to form a planarized hardmask film. The hardmask film may be planarized to form a second backside mask pattern BMP2 having a hole exposing the semiconductor block SB. Afterwards, the semiconductor block SB may be etched by using the second backside mask pattern BMP2 as an etch mask to form a via hole VH exposing a backside surface of the source/drain region 130. A portion of the source/drain region 130 may be etched during the formation of the via hole VH, and thus, the via hole VH may extend into the source/drain region 130.

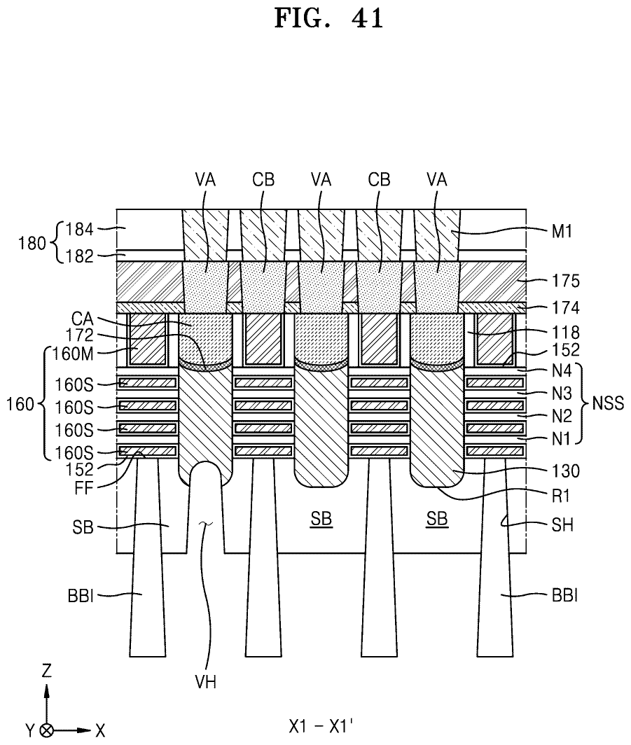

Referring to FIG. 41, the second backside mask pattern BMP2 may be removed from the resultant structure of FIG. 40. When the second backside mask pattern BMP2 includes an SOH material, the second backside mask pattern BMP2 may be removed using ashing and strip processes.

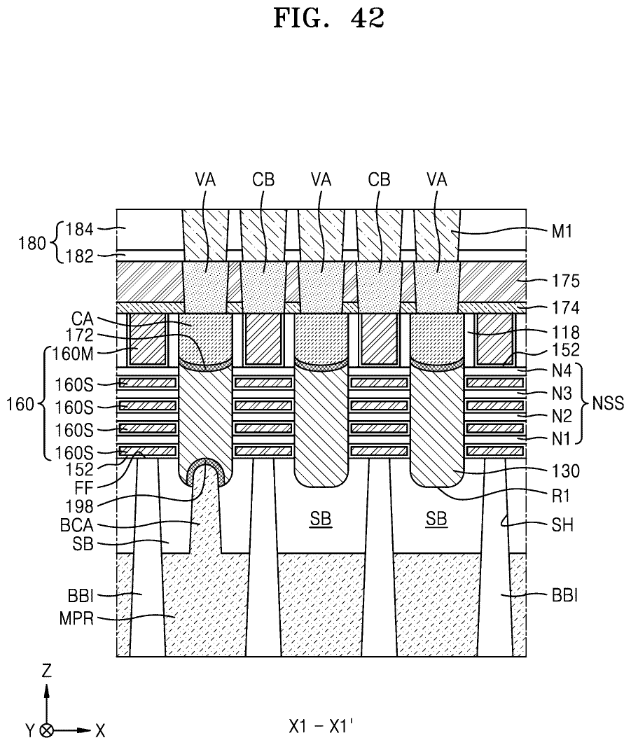

Referring to FIG. 42, in the resultant structure of FIG. 41, respective spaces between the via holes VH and the backside bulk insulating films BBI may be filled by a conductive material to form the backside source/drain contact BCA and the backside power rail MPR, which are shown in FIG. 8A. Thus, the IC device 300 shown in FIGS. 8A and 8B may be manufactured.

Although the IC device 100 shown in FIGS. 2 to 6 and the methods of manufacturing the IC device 300 shown in FIGS. 8A and 8B have been described with reference to FIGS. 9A to 42, it will be understood that the IC device 200 shown in FIG. 7 and variously modified ones of the IC devices 100, 200, and 300 shown in FIGS. 2 to 8B may be manufactured by applying various modifications and changes to the processes described with reference to FIGS. 9A to 42 within the scope of the inventive concept.

While the inventive concept has been particularly shown and described with reference to embodiments thereof, it will be understood that various changes in form and details may be made therein without departing from the spirit and scope of the following claims.

What is claimed is:

1. An integrated circuit device comprising:
a channel region;
a gate line at least partially surrounding the channel region, the gate line having a first top surface extending in a first direction, wherein the first top surface of the gate line is a first distance apart from an uppermost surface of the channel region in a second direction perpendicular to the first direction;
a source/drain region contacting the channel region;
a source/drain contact on the source/drain region and connected to the source/drain region, the source/drain contact having a second top surface coplanar with the first top surface of the gate line and extending in the first direction; and
an etch stop insulating film extending from the first top surface of the gate line toward the second top surface of the source/drain contact in the first direction, the etch stop insulating film contacting the first top surface of the gate line.

2. The integrated circuit device of claim 1, further comprising gate insulating spacers on the channel region, the gate insulating spacers at least partially covering two sidewalls of the gate line,
wherein each of the gate insulating spacers has a spacer top surface coplanar with the first top surface of the gate line and extending in the first direction, and
the etch stop insulating film is in contact with the spacer top surface of each of the gate insulating spacers.

3. The integrated circuit device of claim 1, further comprising an inter-gate dielectric film at least partially covering a sidewall of each of the source/drain region and the source/drain contact,
wherein the inter-gate dielectric film has an insulating top surface coplanar with the first top surface of the gate line and extending in the first direction, and
the etch stop insulating film is in contact with the insulating top surface of the inter-gate dielectric film.

4. The integrated circuit device of claim 1, further comprising:
a gate contact passing through the etch stop insulating film in the second direction and contacting the first top surface of the gate line; and
a via contact passing through the etch stop insulating film in the second direction and contacting the second top surface of the source/drain contact,
wherein a third top surface of the gate contact and a fourth top surface of the via contact are coplanar in the first direction and are a second distance from the uppermost surface of the channel region in the second direction, the second distance being greater than the first distance.

5. The integrated circuit device of claim 4, further comprising a capping insulating film on a top surface of the etch stop insulating film, the capping insulating film at least partially surrounding a sidewall of each of the gate contact and the via contact,
wherein a capping top surface of the capping insulating film is coplanar with the top surface of the gate contact and extends in the first direction.

6. The integrated circuit device of claim 4, further comprising a capping insulating film at least partially surrounding a sidewall of each of the gate contact and the via contact,
wherein a bottom surface of the capping insulating film is in contact with a top surface of the etch stop insulating film, and
the etch stop insulating film and the capping insulating film comprise different insulating materials.

7. The integrated circuit device of claim 4, further comprising a capping insulating film at least partially surrounding a sidewall of each of the gate contact and the via contact,
wherein the etch stop insulating film comprises a silicon oxide film, an aluminum oxide film, or a combination thereof, and
the capping insulating film comprises a silicon nitride film.

8. The integrated circuit device of claim 1, further comprising a metal silicide film between the source/drain region and the source/drain contact.

9. An integrated circuit device comprising:
a plurality of channel regions apart from each other in a first direction;
a plurality of gate lines at least partially surrounding the plurality of channel regions, each of the plurality of gate lines extending perpendicular to the plurality of channel regions, and each gate line having a first top surface extending in the first direction, wherein the first top surface of the gate line is a first distance apart from an uppermost surface of each of the plurality of channel regions in a second direction perpendicular to the first direction;
a plurality of source/drain regions, each of the plurality of source/drain regions between two adjacent ones of the plurality of gate lines;
a plurality of source/drain contacts, each of the plurality of source/drain contacts connected to a source/drain region of the plurality of source/drain regions, and each of the plurality of source/drain contacts having a second top surface coplanar with the first top surface of the gate line and extending in the first direction; and
an etch stop insulating film extending in the first direction from the first top surface of each of the plurality of gate lines toward the second top surface of a source/drain contact from among the plurality of source/drain contacts, the etch stop insulating film contacting the first top surface of each of the plurality of gate lines.

10. The integrated circuit device of claim 9, further comprising a plurality of gate insulating spacers at least partially covering two sidewalls of the plurality of gate lines,
wherein each of the plurality of gate insulating spacers has a spacer top surface coplanar with the first top surface of the gate line and extending in the first direction, and
the etch stop insulating film is in contact with the spacer top surface of each of the plurality of gate insulating spacers.

11. The integrated circuit device of claim 9, further comprising:
at least one gate contact passing through the etch stop insulating film in the second direction and contacting the first top surface of at least one of the plurality of gate lines; and
at least one via contact passing through the etch stop insulating film in the second direction and contacting the second top surface of at least one of the plurality of source/drain contacts,
wherein each of a third top surface of the at least one gate contact and a fourth top surface of the at least one via contact is a second distance apart from an uppermost surface of each of the plurality of channel regions in the second direction, the second distance being greater than the first distance.

12. The integrated circuit device of claim 11, further comprising a capping insulating film on a top surface of the etch stop insulating film, the capping insulating film at least partially surrounding a sidewall of each of the plurality of gate contacts and the plurality of via contacts,
wherein a capping top surface of the capping insulating film is coplanar with the third top surface of the at least one gate contact and extends in the first direction.

13. The integrated circuit device of claim 11, further comprising a capping insulating film on a top surface of the etch stop insulating film, the capping insulating film at least partially surrounding a sidewall of each of the plurality of gate contacts and the plurality of via contacts,
wherein a bottom surface of the capping insulating film is in contact with a top surface of the etch stop insulating film, and
the etch stop insulating film and the capping insulating film comprise different insulating material.

14. The integrated circuit device of claim 11, further comprising a capping insulating film on a top surface of the etch stop insulating film, the capping insulating film at least partially surrounding a sidewall of each of the plurality of gate contacts and the plurality of via contacts,
wherein the etch stop insulating film comprises a silicon oxide film, an aluminum oxide film, or a combination thereof, and
the capping insulating film comprises a silicon nitride film.

15. The integrated circuit device of claim 9, further comprising a fin-type active region contacting a bottom surface of each of the plurality of source/drain regions, the fin-type active region extending lengthwise in the first direction,
wherein the fin-type active region is apart from the etch stop insulating film with the plurality of source/drain regions therebetween.

16. The integrated circuit device of claim 9, further comprising:
a backside source/drain contact configured to be connected to a first source/drain region selected from the plurality of source/drain regions; and
a backside power rail connected to the backside source/drain contact,
wherein the backside power rail is apart from the etch stop insulating film with the first source/drain region therebetween.

17. The integrated circuit device of claim 9, wherein each of the plurality of channel regions comprises a nanosheet stack comprising a plurality of nanosheets, the plurality of nanosheets overlapping each other in the second direction, and
each of the plurality of gate lines at least partially surrounds the plurality of nanosheets.

18. An integrated circuit device comprising:
a nanosheet stack comprising a plurality of nanosheets extending in a first direction and stacked in a second direction perpendicular to the first direction;
a plurality of gate lines at least partially surrounding the plurality of nanosheets and extending lengthwise in a third direction perpendicular to the first direction and the second direction;
a plurality of gate insulating spacers at least partially covering both sidewalls of each of the plurality of gate lines;
a source/drain region between two adjacent ones of the plurality of gate lines, the source/drain region contacting the plurality of nanosheets;
a source/drain contact on the source/drain region and connected to the source/drain region;
an etch stop insulating film contacting a first top surface of each of the plurality of gate lines and a spacer top surface of each of the plurality of gate insulating spacers;
a capping insulating film on a top surface of the etch stop insulating film, the capping insulating film comprising a different material from a constituent material of the etch stop insulating film;
a plurality of gate contacts passing through the capping insulating film and the etch stop insulating film in the second direction, each of the plurality of gate contacts contacting the first top surface of a corresponding one of the plurality of gate lines; and
a via contact passing through the capping insulating film and the etch stop insulating film in the second direction and contacting a second top surface of the source/drain contact,
wherein the first top surface of each of the plurality of gate lines and the second top surface of the source/drain contact are coplanar and extend in the first direction and the third direction, wherein the first top surface of each of the plurality of gate lines is a first distance apart from a an uppermost surface of the nanosheet stack in the second direction, and
a third top surface of each of the plurality of gate contacts and a fourth top surface of the via contact are coplanar in the first direction, and are a second distance apart from the uppermost surface of the nanosheet stack in the second direction, and the second distance is greater than the first distance.

19. The integrated circuit device of claim 18, wherein the etch stop insulating film comprises a silicon oxide film, an aluminum oxide film, or a combination thereof, and
the capping insulating film comprises a silicon nitride film.

20. The integrated circuit device of claim 18, further comprising an inter-gate dielectric film at least partially covering a sidewall of each of the source/drain region and the source/drain contact in the third direction,
wherein the inter-gate dielectric film has an insulating top surface are coplanar with the first top surface of each of the plurality of gate lines and extend in the first direction, and
the etch stop insulating film is in contact with the insulating top surface of the inter-gate dielectric film.
